(19) United States
(12) Patent Application Publication
(10) Pub. No.: US 2018/0309091 A1
(43) Pub. Date: Oct. 25, 2018

(54) RESTRICTION UNIT, VAPOR DEPOSITION DEVICE, PRODUCTION METHOD FOR VAPOR DEPOSITION FILM, PRODUCTION METHOD FOR ELECTROLUMINESCENCE DISPLAY DEVICE, AND ELECTROLUMINESCENCE DISPLAY DEVICE

(71) Applicant: Sharp Kabushiki Kaisha, Sakai City, Osaka (JP)

(72) Inventors: Yuhki KOBAYASHI, Sakai City (JP); Katsuhiro KIKUCHI, Sakai City (JP); Shinichi KAWATO, Sakai City (JP); Satoshi INOUE, Sakai City (JP); Manabu NIBOSHI, Sakai City (JP)

(21) Appl. No.: 15/769,405

(22) PCT Filed: Oct. 13, 2016
(86) PCT No.: PCT/JP2016/080370

§ 371 Date: Apr. 19, 2018

(30) Foreign Application Priority Data
Oct. 20, 2015 (JP) 2015-206575

(51) Int. Cl. H01L 51/56; C23C 16/455; C23C 14/04; H01L 27/32; H01L 51/00

(52) U.S. Cl. CPC H01L 51/56; C23C 16/45591; H01L 51/0011; H01L 27/3244; H01L 51/001; C23C 14/042

(57) ABSTRACT

A restriction unit includes at least one restriction opening configured to allow vapor deposition particles to pass through and a plurality of restriction sections prepared at both sides of the restriction opening. The restriction section has a cross-sectional shape of an inverse concave formed of a top wall and opening walls.

### TECHNICAL FIELD

The present disclosure relates to a restriction unit configured to restrict the passage of vapor deposition particles at a time of forming a vapor deposition film of a predetermined pattern on a target film forming substrate, a vapor deposition device including the restriction unit, a production method for a vapor deposition film for producing a vapor deposition film by using the vapor deposition device, a production method for an electroluminescence display device, and the electroluminescence display device.

### BACKGROUND ART

An electro luminescence (hereinafter, “electro luminescence” is referred to as “EL”) display device equipped with an EL element making use of EL of an organic or inorganic material is a complete solid-state device, has self-luminosity, and is excellent in terms of low voltage driving and high responsiveness; such EL display device has been developed as a candidate of a next-generation display technology.

In general, an EL element is film-formed by a vacuum vapor deposition technique in which vapor deposition particles (target film formation components) are vapor-deposited on a target film forming substrate under reduced pressure (under high vacuum) through a vapor deposition mask (also called a shadow mask) where openings are formed in a predetermined pattern. At this time, a scan vapor deposition technique has promise as a large-size substrate film formation technique using a large-size substrate such as a mother substrate as the target film forming substrate. In this technique, a vapor deposition mask, a vapor deposition source, or the like whose size is equivalent to that of the large-size target film forming substrate is unnecessary.

In the scan vapor deposition technique, vapor deposition particles are vapor-deposited in all target film forming regions of the target film forming substrate while scanning the target film forming substrate by relatively moving at least one of the target film forming substrate and a set of the vapor deposition mask and the vapor deposition source by, for example, integrating the vapor deposition mask and the vapor deposition source, or the like. For the vapor deposition source, such a vapor deposition source is used that a plurality of vapor deposition source openings (nozzle section) used as emission openings through which vapor deposition particles are emitted are provided corresponding to each of the target film forming regions arranged in a direction orthogonal to a scanning direction in the target film forming substrate, at a constant pitch in the direction orthogonal to the scanning direction, for example.

As such, a restriction unit configured to restrict the passage of vapor deposition particles is provided in an emission path of the vapor deposition particles traveling from the vapor deposition source toward the target film forming substrate, in such a manner as to prevent the vapor deposition particles emitted from each of the vapor deposition source openings from being deposited in a region other than the target film forming region corresponding to each vapor deposition source opening.

For example, PTL 1 discloses a deposition preventing plate, as a restriction unit, including openings (restriction openings) each corresponding to a panel pattern section of a target film forming substrate. The deposition preventing plate disclosed in PTL 1 has a structure in which a plurality of openings are provided in a plate-like member, and a non-opening functions as a deposition preventing section (restriction section) configured to block or suppress a vapor deposition material supplied to a region other than a formation region of the panel pattern section in the target film forming substrate (in other words, a region other than the target film forming region).

PTL 1 states that, with the above-discussed scheme, useless usage of the vapor deposition material is prevented, and a recovery rate of the vapor deposition material having been not effectively used is raised.

### CITATION LIST

### Patent Literature

PTL 1: JP 2004-199919 A (published on Jul. 15, 2004)

### SUMMARY

### Technical Problem

However, in the scan vapor deposition technique, since a gap is formed between the vapor deposition mask and the target film forming substrate, there is a case in which a tiny film is generated in a region other than a desired region in the target film forming substrate even in a case where the restriction unit is used. Such tiny film brings about a decrease in display quality such as display failure. As such, with the scan vapor deposition technique, the resolution of an obtainable film formation pattern is limited, thereby reducing versatility thereof.

FIGS. 16A and 16B are diagrams each illustrating a film formation state when film-forming a vapor deposition film 302 on a target film forming substrate 200 with the scan vapor deposition technique using a known restriction unit 500. Specifically, FIG. 16A illustrates an ideal film formation state, while FIG. 16B illustrates an actual film formation state.

A Y-axis in each of FIGS. 16A and 16B indicates a horizontal direction axis along a scanning direction on the target film forming substrate 200; an X-axis in each thereof indicates another horizontal direction axis along a direction orthogonal to the scanning direction on the target film forming substrate 200; and a Z-axis indicates a vertical direction axis (up-down direction axis), which is orthogonal to the X-axis and the Y-axis, is a normal direction of a target deposition surface 201 of the target film forming substrate 200, and is also a direction in which a vapor deposition axis line perpendicular to the target deposition surface 201 extends.

As illustrated in FIGS. 16A and 16B, on the target deposition surface 201 of the target film forming substrate 200, a plurality of target film forming regions 202 and non-film forming regions 204 are provided being partitioned. A plurality of target film forming pattern regions 203 where a vapor deposition film 302 is film-formed are provided inside the target film forming region 202. The target film forming region 202 corresponds to the formation region of the panel pattern section in PTL 1.

As illustrated in FIG. 16A, vapor deposition particles 301 emitted from a vapor deposition source opening 31 as an emission opening are restricted in such a manner that the plate-like restriction unit 500 restricts the target film forming region 202 where the vapor deposition particles 301 emitted from each of the vapor deposition source openings 31 are deposited.

The vapor deposition particles 301 emitted from the vapor deposition source opening 31 reaches a vapor deposition mask 10 with an incident angle thereof on a mask opening 12 of the vapor deposition mask 10 being restricted by the particles passing through a restriction plate opening 501 of the restriction unit 500. The vapor deposition particles 301 having passed through the mask opening 12 are deposited on the target film forming substrate 200, whereby a film formation pattern made of the vapor deposition film 302 is formed on the target film forming substrate 200.

Ideally speaking, a film thickness profile to be formed is determined by a nozzle diameter of the vapor deposition source opening 31 and a distance from the vapor deposition mask 10 to the target film forming substrate 200 (size of a gap “g” in the Z-axis direction), and takes a shape illustrated with a solid line in FIG. 17.

FIG. 17 is a graph that shows, taking, as a reference value, the maximum value of the film thickness of the vapor deposition film 302 having been film-formed on the target film forming substrate 200 obtained by simulation as indicated by “Sim” in FIG. 17, the film thickness of the vapor deposition film 302 obtained by the simulation and actual measurement at respective positions in the X-axis direction, where the film thickness is normalized with the above-mentioned reference value.

However, in reality, as illustrated in FIG. 16B, of the vapor deposition particles 301 emitted from the vapor deposition source opening 31, the vapor deposition particles 301 having unfavorable directivity (in other words, the vapor deposition particles 301 spreading in the X-axis direction) are blocked and captured by a plate-like restriction section 502, which is a non-opening. Due to this, a large amount of vapor deposition particles 301 adhere, as vapor deposition objects 303, to a lower face 502a of the restriction section 502, which is also a lower face of the restriction unit 500 (a bottom face thereof, that is, a face opposing the vapor deposition source 30).

Because the vapor deposition particles 301 having adhered to the lower face 502a are close in distance to the vapor deposition source 30 as a heat source, the stated particles re-evaporate by being heated and adhere again as the vapor deposition objects 303 to an upper face 30a (surface) of the vapor deposition source 30.

The vapor deposition objects 303 having adhered again to the upper face 30a of the vapor deposition source 30 re-evaporate again because the vapor deposition source 30 is in a high temperature state. This brings about an effect in which the nozzle diameter is substantially expanded. Due to the vapor deposition objects 303 re-evaporating again, in addition to the vapor deposition particles 301 emitted from the vapor deposition source opening 31 as indicated by a dotted line in FIG. 16B, the vapor deposition particles 301 scattering from a portion other than the vapor deposition source opening 31 enter the mask opening 12 as indicated by an arrow in FIG. 16B. As a result, in addition to the vapor deposition film 302 of a normal pattern (a normal-pattern film), a tiny film 304, which is an abnormal-pattern vapor deposition film, is formed. Consequently, as indicated by a dotted line in FIG. 17, a vapor deposition blur (pattern blur) becomes large to lower the display quality.

As illustrated in FIG. 16B, the tiny film 304 is formed not only on an outer side of the target film forming pattern region 203 but also formed on the whole region including a center portion of the target film forming pattern region 203.

Accordingly, in the case of using the restriction unit 500, it is important to suppress the vapor deposition objects 303 adhering again to the vapor deposition source due to the re-evaporation of the vapor deposition objects 303 having adhered to the lower face 502a.

However, PTL 1 touches upon only the control of the flow of vapor deposition particles (vapor deposition flow), and touches upon neither the spread of vapor deposition particles between the vapor deposition source and the deposition preventing plate as a control unit nor the re-evaporation of the vapor deposition objects adhering to the lower face of the deposition preventing plate in any way.

The present disclosure has been conceived in view of the above problems, and an object thereof is to provide a restriction unit capable of suppressing re-evaporation of vapor deposition objects adhering to a face of the restriction unit opposing a vapor deposition source, a vapor deposition device, a production method for a vapor deposition film, a production method for an electroluminescence display device including a vapor deposition film of a highly precise pattern without adhesion of a tiny film due to the re-evaporation of the above vapor deposition objects, and the electroluminescence display device.

### Solution to Problem

To address the above issues, a restriction unit according to an aspect of the present disclosure is a restriction unit that is configured to restrict the passage of vapor deposition particles emitted from a vapor deposition source and includes at least one opening configured to allow the vapor deposition particles to pass through and a plurality of non-openings prepared at both sides of the above opening. In the stated restriction unit, the non-opening has a cross-sectional shape of an inverse concave formed of a top wall and opening walls.

To address the above issues, a vapor deposition device according to an aspect of the present disclosure includes the restriction unit and the vapor deposition source that is disposed opposing the restriction unit and emits the vapor deposition particles.

To address the above issues, a production method for a vapor deposition film according to an aspect of the present disclosure includes forming a vapor deposition film of a predetermined pattern on a target film forming substrate using the above vapor deposition device.

To address the above issues, a production method for an electroluminescence display device according to an aspect of the present disclosure includes the production method for the vapor deposition film according to the above-mentioned aspect of the present disclosure.

To address the above issues, an electroluminescence display device according to an aspect of the present disclosure is an electroluminescence display device in which a first electrode, an electroluminescence layer formed of an organic or inorganic layer, and a second electrode are provided in that order on a substrate. In the stated electroluminescence display device, the electroluminescence layer includes a light emitting layer formed of a pattern of a vapor deposition film that is formed by vapor deposition particles having passed through an opening of a restriction unit including at least one opening configured to allow the vapor deposition particles emitted from a vapor deposition source to pass through and a plurality of non-openings prepared at both sides of the above opening where the non-opening has a cross-sectional shape of an inverse concave formed of a top wall and opening walls.

### Advantageous Effects of Disclosure

According to the aspects of the present disclosure, the following can be provided: a restriction unit capable of suppressing the re-evaporation of vapor deposition objects adhering to a face of the restriction unit opposing a vapor deposition source, a vapor deposition device, a production method for a vapor deposition film, a production method for an electroluminescence display device including a vapor deposition film of a highly precise pattern without the adhesion of a tiny film due to the re-evaporation of the above vapor deposition objects, and the electroluminescence display device.

### BRIEF DESCRIPTION OF DRAWINGS

FIG. 1 is a cross-sectional view illustrating a schematic configuration of a main portion of a vapor deposition device according to a first embodiment of the present invention.

FIG. 2 is a perspective view illustrating a basic configuration of the vapor deposition device according to the first embodiment of the present invention.

FIG. 3A is a cross-sectional view illustrating an example of a schematic configuration of an organic EL display device produced in the first embodiment of the present invention, and FIG. 3B is a plan view illustrating a schematic configuration of a sub pixel of the organic EL display device illustrated in FIG. 3A.

FIG. 4 is a flowchart illustrating production processes of the organic EL display device illustrated in FIGS. 3A and 3B in the order of the processes to be carried out.

FIG. 5 is a cross-sectional view illustrating an example of an effect by a restriction unit according to the first embodiment of the present invention.

FIGS. 6A and 6B are cross-sectional views illustrating an example of an effect by the restriction unit according to the first embodiment of the present invention compared to a case in which a cross-section of a restriction section is formed in a T shape.

FIG. 7 is a cross-sectional view illustrating a schematic configuration of a main portion of a vapor deposition device according to a first modification on the first embodiment of the present invention.

FIG. 8 is a cross-sectional view illustrating a schematic configuration of a main portion of a vapor deposition device according to a second embodiment of the present invention.

FIGS. 9A and 9B are cross-sectional views each schematically illustrating the configuration of a main portion of the vapor deposition device according to the second embodiment of the present invention.

FIG. 10 is a cross-sectional view explaining a vapor deposition angle of the vapor deposition device according to the second embodiment of the present invention.

FIG. 11 is a cross-sectional view explaining a taper angle of an opening wall of a restriction unit according to the second embodiment of the present invention.

FIG. 12 is another cross-sectional view explaining a taper angle of an opening wall of the restriction unit according to the second embodiment of the present invention.

FIG. 13 is a cross-sectional view illustrating an effect by the restriction unit according to the second embodiment of the present invention.

FIG. 14 is a cross-sectional view illustrating a schematic configuration of a main portion of a vapor deposition device according to a third embodiment of the present invention.

FIG. 15 is a cross-sectional view illustrating an effect by the restriction unit according to the third embodiment of the present invention.

FIGS. 16A and 16B are diagrams each illustrating a film formation state when film-forming a vapor deposition film on a target film forming substrate with the scan vapor deposition technique using a known restriction unit. Specifically, FIG. 16A illustrates an ideal film formation state, while FIG. 16B illustrates an actual film formation state.

FIG. 17 is a graph that shows, taking the maximum value of a film thickness of a vapor deposition film having been film-formed on a target film forming substrate as a reference value, the film thickness of the vapor deposition film obtained by the simulation and actual measurement at respective positions in a direction orthogonal to a scanning direction, where the film thickness is normalized with the above-mentioned reference value.

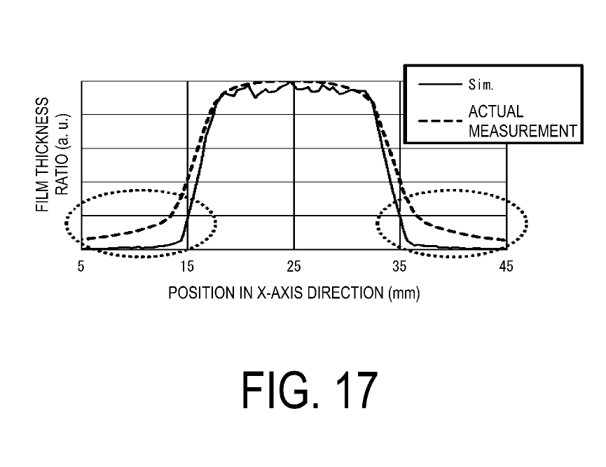

FIG. 18 is a cross-sectional view indicating a problematic point in a case where a distance from a lower face of a restriction section of the restriction unit to an upper face of a vapor deposition source is made larger than that illustrated in FIGS. 16A and 16B.

### DESCRIPTION OF EMBODIMENTS

A detailed description follows regarding embodiments of the present invention.

### First Embodiment

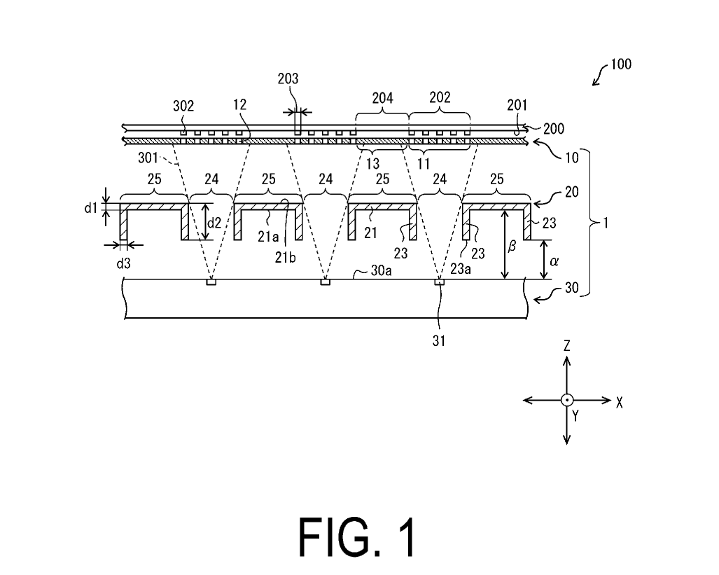

With reference to FIGS. 1 to 7, FIGS. 16A and 16B, and FIG. 18, embodiments of the present invention will be described as follows.

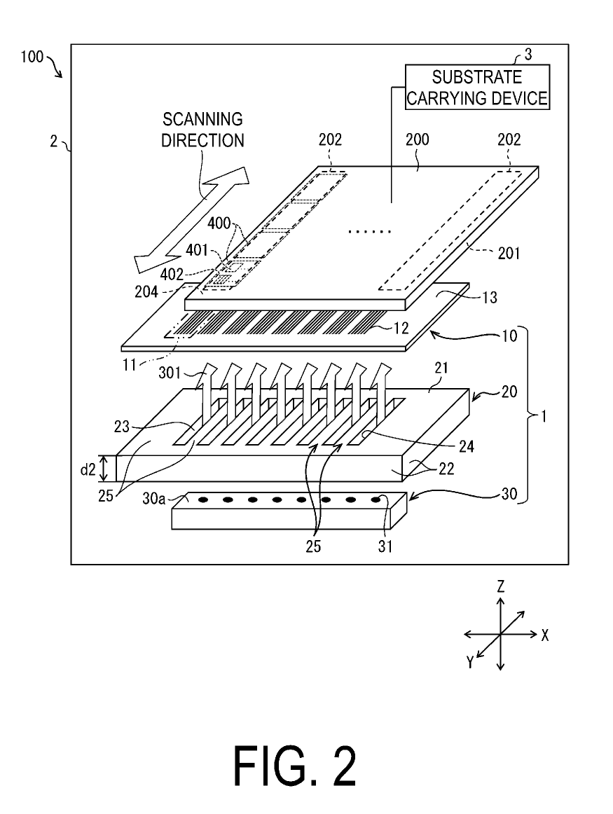

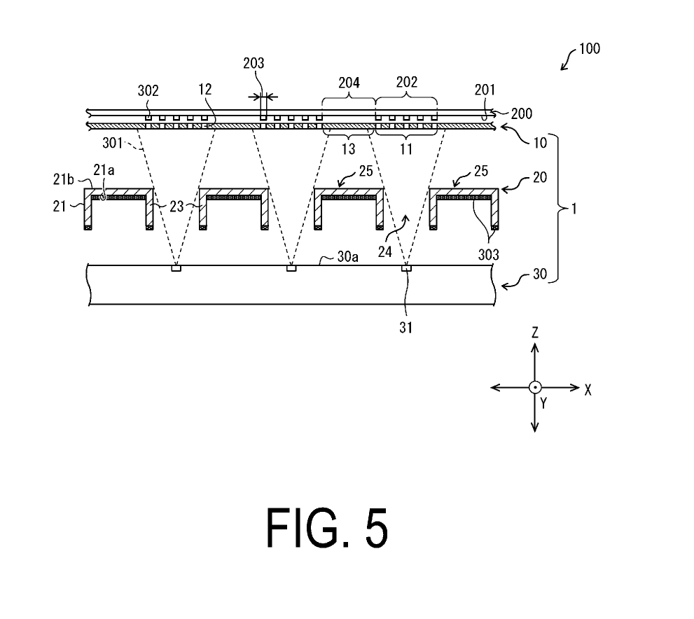

In FIG. 1, FIG. 2, and FIGS. 5 to 7, for the sake of convenience in illustration, the numbers of mask openings and restriction openings, the numbers of target film forming regions and target film forming pattern regions, the number of pixels, and the like are reduced in the drawings.

FIG. 1 is a cross-sectional view illustrating a schematic configuration of a main portion of a vapor deposition device 100 according to the present embodiment. FIG. 2 is a perspective view illustrating a basic configuration of the vapor deposition device 100 according to the present embodiment.

The vapor deposition device 100 and a vapor deposition technique according to the present embodiment are particularly useful for vapor deposition of an EL layer such as a light emitting layer configuring an EL element in an EL display device such as an organic EL display device.

Hereinafter, exemplified is a case in which the vapor deposition device 100 and the vapor deposition technique according to the present embodiment are applied to a production of an RGB full color-display organic EL display device where organic EL elements of red (R), green (G), and blue (B) colors are arranged as sub pixels on a substrate thereof, and a light emitting layer of the organic EL element is film-formed by an RGB selective patterning method, for example.

In other words, hereinafter, a case in which a vapor deposition film 302 film-formed by the vapor deposition device 100 according to the present embodiment is a light emitting layer for each color of R, G, and B in the organic EL display device is exemplified and described. Note that, however, the present embodiment is not limited thereto, and the vapor deposition device 100 and the vapor deposition technique according to the present embodiment can be generally applied to the productions of devices using a vapor-phase growth technique including, as representative examples, the productions of organic EL display devices and inorganic EL display devices.

In the following description as well, a horizontal direction axis along a scanning direction on a target film forming substrate 200 is taken as a Y-axis; another horizontal direction axis along a direction orthogonal to the scanning direction on the target film forming substrate 200 is taken as an X-axis; and a vertical direction axis (up-down direction axis) that is orthogonal to the X-axis and the Y-axis, and is a normal direction of a target deposition surface 201 of the target film forming substrate 200 is taken as a Z-axis. For the sake of convenience in description, unless otherwise specifically mentioned, a side of an upward arrow in the Z-axis direction is taken as an upper side in the following description. In addition, unless otherwise specifically mentioned, “cross section” refers to a cross section parallel to the X-axis direction.

### Schematic Configuration of Vapor Deposition Device 100

As illustrated in FIGS. 1 and 2, the vapor deposition device 100 is a device configured to film-form the vapor deposition film 302 in a target film forming region 202 on the target deposition surface 201 of the target film forming substrate 200 by a scan vapor deposition technique using a restriction unit 20.

The vapor deposition device 100 according to the present embodiment includes, as absolutely necessary constituent elements, a vapor deposition mask 10, the restriction unit 20, and a vapor deposition source 30.

A positional relationship among the vapor deposition mask 10, the restriction unit 20, and the vapor deposition source 30 is fixed. The restriction unit 20 and the vapor deposition source 30 may be respectively fixed within a film formation space (e.g., an inner wall of a film formation chamber 2), or may be unitized as a vapor deposition unit 1 whereby the positional relationship between them may be fixed. The vapor deposition mask 10, the restriction unit 20, and the vapor deposition source 30 may be fixed to each other with, for example, a rigid member (not illustrated) such as a holder (holding member), or may have independent configurations and operate as the vapor deposition unit 1 with a single control operation. At least one of the target film forming substrate 200 and a set of the vapor deposition mask 10, the restriction unit 20 and the vapor deposition source 30 relatively moves with respect to the other along the Y-axis direction which is the scanning direction as illustrated in FIG. 2, whereby the vapor deposition film 302 is consequently formed in all the target film forming regions 202 of the target film forming substrate 200.

The vapor deposition device 100 according to the present embodiment includes, for example, the film formation chamber 2, a substrate carrying device 3 (substrate movement device), the vapor deposition mask 10, the restriction unit 20, the vapor deposition source 30, and further includes a mask holder, a substrate holder, a restriction unit holder, a deposition preventing member, a shutter, a control device, and the like (not illustrated).

Next, more detailed description follows regarding each of the configurations.

### Target Film Forming Substrate 200

The target film forming substrate 200 used in the present embodiment will be described first.

As illustrated in FIGS. 1 and 2, on the target deposition surface 201 of the target film forming substrate 200, the plurality of target film forming regions 202 are provided being partitioned.

The target film forming substrate 200 is a mother substrate. In a mass-production process, a plurality of organic EL display devices 400 are formed on the mother substrate, and thereafter are divided into each individual organic EL display device 400.

The target film forming regions 202 are formed in a stripe pattern from one end to the other end of the target film forming substrate 200. In the periphery of each target film forming region 202, a non-film forming region 204 is provided to surround each target film forming region 202.

In each of the target film forming regions 202, provided are a plurality of pixel areas where a plurality of pixels 401 of the organic EL display devices 400 are arranged. With this, on the target film forming substrate 200, the pixel areas of the organic EL display devices 400 are formed in a two-dimensional (matrix) pattern.

Each of the pixels 401 in the pixel areas includes sub pixels 402 of colors of R, G, and B. As such, in each of the target film forming regions 202, a plurality of sub pixels 402 of respective colors made of organic EL elements of R, G, and B colors are provided, and a fine vapor deposition film pattern that is made of the vapor deposition films 302 of R, G, and B colors and is used as a light emitting layer of the organic EL element is formed as the vapor deposition film 302 in each sub pixel 402.

Although not illustrated, in the present embodiment, a drive circuit of the organic EL display device 400 and one of a pair of electrodes prepared at both sides of the light emitting layer in the organic EL element are formed in advance in each of the target film forming regions 202.

As illustrated in FIG. 1, in each target film forming region 202, the plurality of target film forming pattern regions 203 forming the vapor deposition films 302 of the above-mentioned colors are provided corresponding to the respective sub pixels 402.

The target film forming substrate 200 is held by a substrate holder (not illustrated). In a case where the vapor deposition mask 10, the restriction unit 20, and the vapor deposition source 30 are relatively moved with respect to the target film forming substrate 200 (in other words, in the case where, of the target film forming substrate 200 and the vapor deposition unit 1, only the vapor deposition unit 1 is moved), the substrate holder may be fixed to an inner wall of the film formation chamber 2.

### Vapor Deposition Mask 10

As illustrated in FIG. 2, the vapor deposition mask 10 is a plate-like member in which a mask face as its principal face is in parallel to an X-Y plane. When performing the scan vapor deposition, a vapor deposition mask smaller in size at least in the Y-axis direction than the target film forming substrate 200 in plan view is used for the vapor deposition mask 10. Here, the “in plan view” refers to “as seen from a direction orthogonal to the principal face of the vapor deposition mask 10 (that is, a direction parallel to the Z-axis)”.

The vapor deposition mask 10 is held by a mask holder (not illustrated). In a case where only the target film forming substrate 200 is relatively moved with respect to the vapor deposition mask 10, the restriction unit 20, and the vapor deposition source 30, the mask holder may be fixed to the inner wall of the film formation chamber 2.

The vapor deposition mask 10 may be used as is, or may be fixed to a mask frame (not illustrated) in a state of tensile force being applied thereto in order to suppress self-weight bending. The mask frame is formed in a rectangular shape whose outer shape is the same as, or is a size slightly larger than that of the vapor deposition mask 10 in plan view.

As illustrated in FIGS. 1 and 2, the vapor deposition mask 10 includes a plurality of mask opening regions 11 opposing the target film forming regions 202 of the target film forming substrate 200 when the mask opposes the target film forming substrate 200. In the mask opening region 11, there are provided a plurality of openings (through-holes), as mask openings 12, that function as passage ports to allow vapor deposition particles 301 (vapor deposition material) to pass through. The mask openings 12 correspond to part of the patterns of the vapor deposition films 302. The mask opening region 11 is configured of a group of the mask openings 12. A region other than the mask opening 12 in the vapor deposition mask 10 is a non-opening 13 (non-opening region) and functions as a blocking section configured to block a flow of the vapor deposition particles 301 (vapor deposition flow).

The mask openings 12 are provided corresponding to part of the patterns of the vapor deposition films 302 film-formed by the vapor deposition mask 10 in use so that the vapor deposition particles 301 do not adhere to a region other than the target film forming pattern region 203 as a film formation target on the target film forming substrate 200.

As illustrated in FIG. 1, only the vapor deposition particles 301 having passed through the mask openings 12 reach the target film forming substrate 200, whereby the vapor deposition films 302 in the patterns corresponding to the mask openings 12 are formed on the target film forming substrate 200.

In an example illustrated in FIG. 2, in each of the mask opening regions 11, the plurality of mask openings 12 each formed in an elongated slit shape extending in a column direction are provided being aligned in the X-axis direction. However, the mask opening 12 may be formed in a slot shape, for example. The shape in plan view and the number of the mask opening 12 and the mask opening region 11 are not specifically limited.

In addition, the material of the vapor deposition mask 10 is not limited to any specific one. The material of the vapor deposition mask 10 may be metal such as Invar (iron-nickel alloy), or may be resin or ceramics, or may be a material in which the cited materials are combined.

### Vapor Deposition Source 30

The vapor deposition source 30 is, for example, a container configured to store a vapor deposition material therein. The vapor deposition source 30 may be a container configured to directly store the vapor deposition material in the interior of the container, or may be formed in such a manner as to include load-lock type piping and be supplied with the vapor deposition material from exterior.

The vapor deposition source 30 is formed in a rectangular shape as illustrated in FIG. 2, for example. A plurality of vapor deposition source openings 31 (emission openings, or a nozzle section) are provided, as emission openings for emitting the vapor deposition particles 301, in an upper face 30a of the vapor deposition source 30 (in other words, a face opposing the restriction unit 20). The vapor deposition source openings 31 are arranged at a constant pitch in the X-axis direction.

The vapor deposition source 30 generates the vapor deposition particles 301 in a gaseous state by heating the vapor deposition material to evaporate it (in the case of the vapor deposition material being a liquid one) or sublimate it (in the case of the vapor deposition material being a solid one). The vapor deposition source 30 emits the vapor deposition material, having been gasified in the above manner, as the vapor deposition particles 301 toward the restriction unit 20 from the vapor deposition source openings 31.

In the present embodiment, as discussed above, a line vapor deposition source (line source) including the plurality of vapor deposition source openings 31 can be used as the vapor deposition source 30, and moreover it is possible to perform uniform film formation on the target film forming substrate 200 having a large area by moving the vapor deposition source 30 in the Y-axis direction. In this case, a decrease in throughput is not generated at the time of mass production, which is a large advantage of the present embodiment.

The vapor deposition source 30 may be held by a vapor deposition source holder (not illustrated), or may be fixed to the inner wall of the film formation chamber 2 in the case where only the target film forming substrate 200 is relatively moved with respect to the vapor deposition mask 10, the restriction unit 20, and the vapor deposition source 30.

### Restriction Unit 20

The restriction unit 20 is provided between the vapor deposition mask 10 and the vapor deposition source 30, as illustrated in FIGS. 1 and 2.

The restriction unit 20 is held by a restriction unit holder (not illustrated). In the case where only the target film forming substrate 200 is relatively moved with respect to the vapor deposition mask 10, the restriction unit 20, and the vapor deposition source 30, the restriction unit holder may be fixed to the inner wall of the film formation chamber 2.

The restriction unit 20 is provided being distanced from the vapor deposition mask 10 and the vapor deposition source 30, and controls an isotropic flow of the vapor deposition particles 301 (vapor deposition flow) emitted from the vapor deposition source opening 31 to enhance the directivity.

In the present embodiment, since the scan vapor deposition is carried out as discussed above, any of the vapor deposition mask 10, the restriction unit 20, and the vapor deposition source 30 is formed to be smaller in size in the Y-axis direction than the target film forming substrate 200 in plan view. The size of the restriction unit 20 is equal to or larger than that of the vapor deposition mask 10 in plan view.

The restriction unit 20 is a hollow block-shaped unit without a base (in other words, a reverse tray-shaped unit) that is configured by a plate-like top wall 21 as a transverse plate disposed in the horizontal direction, a plurality of plate-like side walls 22 as longitudinal plates (vertical walls) each disposed in a direction intersecting with the horizontal direction, and a plurality of plate-like opening walls 23 (nozzle walls). The restriction unit 20 includes a plurality of restriction openings 24 as nozzle-like openings (through-holes) surrounded by the opening walls 23, and a restriction section 25 as a non-opening configured by the top wall 21, the side walls 22, and the opening walls 23.

The side walls 22 are formed projecting downward on the periphery of the top wall 21 while surrounding the top wall 21. The opening walls 23 are formed projecting downward on the periphery of each of the restriction openings 24 while surrounding the restriction opening 24.

In the present embodiment, the side walls 22 are vertically provided downward (vertically hung) from the top wall 21 in parallel to a normal direction of the top wall 21 in such a manner as to surround the top wall 21. The opening walls 23 are vertically provided downward (vertically hung) from the top wall 21 in parallel to the normal direction of the top wall 21 in such a manner as to surround the restriction opening 24.

The restriction openings 24 are arranged in the top wall 21 at a constant pitch along the X-axis direction in plan view. The restriction openings 24 each function as a passage port to allow the vapor deposition particles 301 (vapor deposition material) to pass through.

A portion other than the restriction opening 24 in the restriction unit 20 is the restriction section 25 as the non-opening. The restriction section 25 is a blocking section configured to block the flow of the vapor deposition particles 301, and takes a role of restricting an incident angle of the vapor deposition particles 301 entering the mask openings 12 of the vapor deposition mask 10.

The restriction unit 20 prevents, with the restriction section 25, the passage of the vapor deposition particles 301 supplied to a region other than the target film forming pattern region 203 in the target film forming substrate 200, and enhances the directivity of the vapor deposition particles 301 passing through the restriction openings 24.

As illustrated in FIG. 1, the vapor deposition particles 301 emitted from the vapor deposition source opening 31 arrive at the vapor deposition mask 10 while the incident angle of the vapor deposition particles 301 on the mask opening 12 being restricted by the particles passing through the restriction opening 24. The vapor deposition particles 301 having passed through the mask opening 12 are deposited on the target film forming substrate 200, whereby a film formation pattern made of the vapor deposition film 302 is formed on the target film forming substrate 200.

The restriction unit 20 partitions a space between the vapor deposition mask 10 and the vapor deposition source 30 into a plurality of vapor deposition spaces configured of the restriction openings 24 by the restriction sections 25.

The restriction opening 24 and the target film forming region 202 have a one-on-one relationship. Accordingly, the restriction opening 24 and the mask opening region 11 have a one-on-one relationship.

The pitch of the restriction openings 24 is formed to be larger than the pitch of the mask openings 12, and the plurality of mask openings 12 are arranged between the restriction sections 25 adjacent to each other at both sides of the restriction opening 24 in the X-axis direction in plan view.

The restriction openings 24 and the vapor deposition source openings 31 are formed at the same pitch in the X-axis direction. Due to this, the restriction openings 24 and the vapor deposition source openings 31 have a one-on-one relationship in the X-axis direction. Each of the vapor deposition source openings 31 is disposed corresponding to each of the restriction openings 24 in such a manner as to be positioned at the center position in the X-axis direction of each restriction opening 24 in plan view (in other words, at the center position in the X-axis direction between the restriction sections 25 adjacent to each other at both sides of each of the vapor deposition source openings 31 in the X-axis direction).

In the present embodiment, as illustrated in FIG. 2, a line vapor deposition source is used for the vapor deposition source 30 in which the vapor deposition source openings 31 are arranged in a one-dimensional form (that is, in a line form) in the X-axis direction. As such, in order to have a one-on-one relationship with each of the restriction openings 24, for example, the vapor deposition source opening 31 is disposed at the center of each restriction opening 24 in plan view (the center in both the X-axis direction and Y-axis direction).

Note that, however, the present embodiment is not limited thereto, and the vapor deposition source openings 31 may be arranged in a two-dimensional form (tiling form) in the X-axis and Y-axis directions. Also, in the case where the vapor deposition source openings 31 are two-dimensionally disposed, it is preferable for each vapor deposition source opening 31 to be so disposed as to be positioned at the center position in the X-axis direction of each restriction opening 24.

As discussed above, the restriction unit 20 according to the present embodiment is constituted of the top wall 21 in which the restriction openings 24 are provided, the side walls 22 that are so provided as to project downward from part of the top wall 21, and the opening walls 23.

Accordingly, a height d2 of the side wall 22 and the opening wall 23 is larger than a thickness d1 of the top wall 21, and each of the restriction sections 25 constituted of the top wall 21 and the side walls 22 or the opening walls 23 has a cross-sectional shape with the base open, that is, a cross-sectional shape of an inverse concave, as illustrated in FIG. 1.

To be more specific, in the present embodiment, each restriction section 25 has a cross-sectional shape of a square with one side on the bottom side being open where the side walls 22 and the opening walls 23 are vertically hung (vertically provided downward) in the vertical direction from the top wall 21.

The thickness d1 of the top wall 21 indicates a length of the top wall 21 in the Z-axis direction (a normal direction of the top wall 21) which is a plate thickness of the top wall 21, that is, a distance from an upper face 21b to a lower face 21a of the top wall 21. The height d2 of the side wall 22 and the opening wall 23 indicates a height in the Z-axis direction of the side wall 22 and the opening wall 23, in other words, a distance in the Z-axis direction from the upper face 21b of the top wall 21 to a lower face 23a of the opening wall 23, and a distance in the Z-axis direction from the upper face 21b of the top wall 21 to a lower face of the side wall 22.

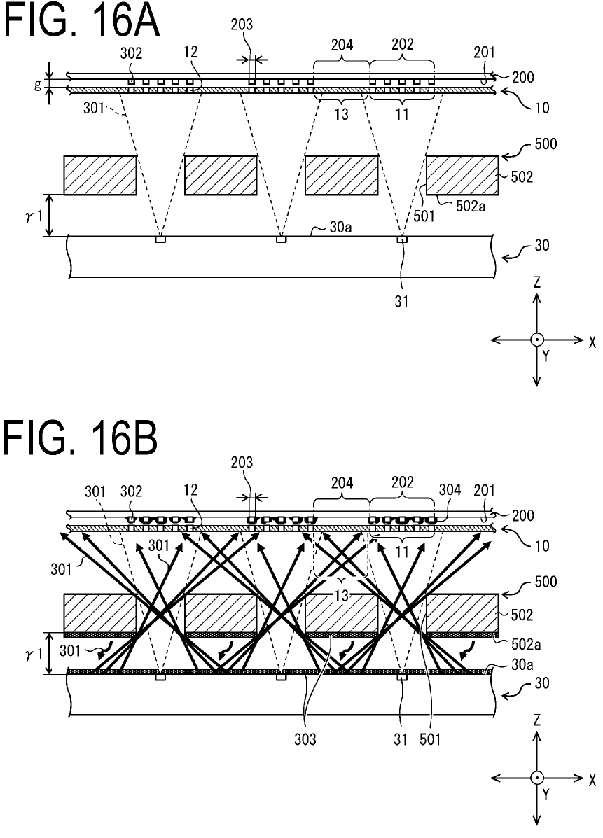

In the known scheme, as illustrated in FIGS. 16A and 16B, in general, the restriction section 502 of the restriction unit 500 is called, for example, a restriction plate, and each of the restriction sections 502 is formed in a plate-like shape with a uniform thickness. For example, the restriction unit 20 described in PTL 1 is a deposition preventing plate, and the whole thereof is formed in a plate-like shape.

As illustrated in FIG. 16B, a large amount of vapor deposition particles 301 adhere, as the vapor deposition objects 303, to a plate bottom, which is the lower face 502a of the restriction section 502, at the time of vapor deposition.

As a method for reducing the re-evaporation of the vapor deposition objects 303 having adhered to the lower face 502a of the restriction section 502 as described above, a method to reduce the area of the lower face 502a of the restriction section 502 (Method 1), for example, can be conceived.

A project area of the restriction section 502 needs to be reduced in order to reduce the amount of vapor deposition objects 303 adhering to the lower face 502a of the restriction section 502 by reducing the area of the lower face 502a of the restriction section 502. However, because the restriction plate opening 501 and the target film forming region 202 correspond to each other on a one-on-one basis, the pitch of the restriction sections 502 adjacent to each other at both sides of the restriction plate opening 501 is changed when the project area of the restriction section 502 is changed. The pitch of the restriction sections 502 cannot be largely changed in consideration of the relationship with the target film forming region 202. Therefore, it is difficult to actually employ Method 1 discussed above.

As another method for reducing the re-evaporation of the vapor deposition objects 303 having adhered to the lower face 502a of the restriction section 502, a method to distance the lower face 502a of the restriction section 502 from the vapor deposition source 30 (Method 2), for example, can be conceived.

According to Method 2 mentioned above, the re-evaporation of the vapor deposition objects 303 can be reduced by reducing the radiation heat from the vapor deposition source 30 toward the vapor deposition objects 303 adhering to the lower face 502a. However, Method 2 mentioned above also has a problem.

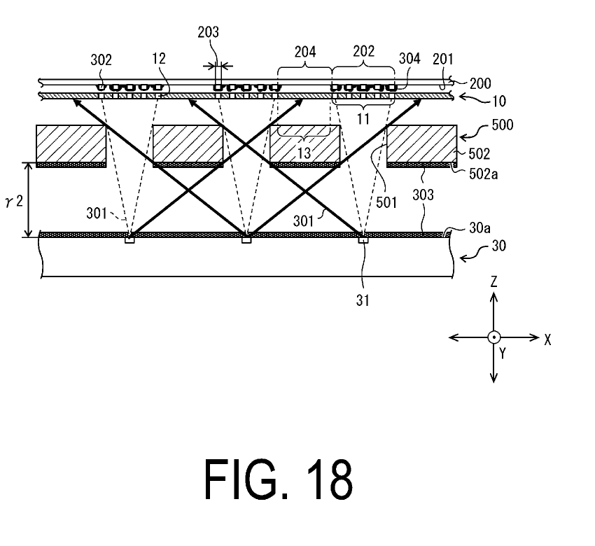

FIG. 18 is a cross-sectional view indicating a problematic point in a case where a distance γ2 from the lower face 502a of the restriction section 502 of the restriction unit 20 to the upper face 30a of the vapor deposition source 30 is made larger than a distance y1 from the lower face 502a of the restriction section 502 of the restriction unit 500 illustrated in FIGS. 16A and 16B to the upper face 30a of the vapor deposition source 30.

As illustrated in FIG. 18, in the case where, for example, the restriction section 502 is further distanced from the vapor deposition source 30 compared to the case illustrated in FIGS. 16A and 16B (that is, γ2>γ1) so as to reduce the radiation heat from the vapor deposition source 30, it is difficult to block the vapor deposition particles 301 being scattered from the vapor deposition source opening 31 (called an “adjacent nozzle” below) adjacent to the vapor deposition source opening 31 ejecting the vapor deposition particles 301 that are originally expected to enter each restriction plate opening 501.

In the case where the vapor deposition particles 301 scattered from the adjacent nozzle and not expected to enter any openings pass through a certain restriction plate opening 501, the vapor deposition particles 301 from the adjacent nozzle are mixed in the vapor deposition film 302 to be film-formed, the scattering of the vapor deposition particles 301 is caused, or the like. The above phenomena cause the tiny film 304 as illustrated in FIG. 16B to be film-formed, thereby raising a possibility that the display quality is significantly degraded.

As another method to distance the lower face 502a of the restriction section 502 from the vapor deposition source 30 as described in Method 2 mentioned above, such a scheme can be conceived that the thickness of the restriction section 502 (in other words, the plate thickness of the restriction plate) is reduced while keeping the position of the upper face of the restriction section 502.

However, in the case where the overall thickness of the restriction section 502 is simply reduced by using, for example, a restriction plate with a thinned plate thickness or the like for the restriction section 502, a physical nozzle length of each of the restriction plate openings 501 is shortened, whereby an effect of improvement in collimator properties of the vapor deposition particles 301 is lowered and it is difficult to block the vapor deposition particles 301 scattering from the adjacent nozzle like in the case illustrated in FIG. 18.

In contrast, by forming the cross section of the restriction section 25 in an inverse concave shape as discussed above, the height d2 of the opening wall 23 that determines the nozzle length of the restriction opening 24 makes it possible to distance most part of the face of the restriction section 25 opposing the vapor deposition source 30 from the vapor deposition source 30 while the height d2 maintaining a range defined by design.

In the present embodiment, as the thickness d1 of the top wall 21 is smaller, the influence of the radiation heat from the vapor deposition source 30 can be preferably reduced. Note that, however, when d1 is excessively small, the strength is lowered and the top wall 21 cannot be kept as a structural member. Accordingly, it is preferable for d1 to be not less than 1 mm, and more preferable to be not less than 5 mm.

The height d2 of the side wall 22 and the opening wall 23, particularly the height d2 of the opening wall 23 is not limited to any specific value as long as the relation of d1<d2 is satisfied as discussed above. As d2 is longer, a difference between d1 and d2 becomes larger and the radiation heat of the vapor deposition source 30 toward the top wall 21 is further reduced, whereby an effect of the reduction in re-evaporation of the vapor deposition objects 303 is further enhanced.

Further, as a thickness d3 of the open wall 23 and the side wall 22, particularly the thickness d3 of the opening wall 23 facing the restriction opening 24 is smaller, an absolute value of the adhesion amount of the vapor deposition objects 303 adhering to the lower face of the restriction section 25, that is, a face of the restriction section 25 opposing the vapor deposition source 30 (in other words, the lower face 23a of the opening wall 23 and the lower face of the side wall 22) can be preferably decreased.

Here, the thickness d3 of the opening wall 23 and the side wall 22 indicates a length in the X-axis direction of each of the opening wall 23 and the side wall 22, which is a plate thickness of the opening wall 23 and the side wall 22. To be more specific, the thickness d3 indicates the length of the lower face 23a of the opening wall 23 and the lower face of the side wall 22 in the X-axis direction of each thereof.

However, when d3 is excessively small, the strength is lowered like in the case of d1 and the wall having such d3 cannot be kept as a structural member. Accordingly, it is preferable for d3 to be not less than 1 mm, and more preferable to be not less than 5 mm.

The values of d1 and d3 may be the same or may be different. However, processing is more easily carried out when the values of d1 and d3 are the same. In other words, the restriction unit 20 can be produced with ease.

In the present embodiment, the following case is exemplified and explained: the height of the opening wall 23 illustrated in FIG. 1 (length in the Z-axis direction) and the height of the side wall 22 illustrated in FIG. 2 (length in the Z-axis direction) are the same (in other words, the height of the opening wall 23=the height of the side wall 22=d2), and the thickness of the opening wall 23 illustrated in FIG. 1 (d3, the length in the X-axis direction) and the thickness of the side wall 22 (length in the X-axis direction, not illustrated) are the same (in other words, the thickness of the opening wall 23=the thickness of the side wall 22=d3), as described above.

However, also in the present embodiment, as long as the height of the opening wall 23 (d2) is larger than the thickness d1 of the top wall 21, it may be acceptable that the height of the opening wall 23 and the height of the side wall 22 are the same or are different.

In the case where, of the vapor deposition particles 301 emitted from the vapor deposition source 30, unnecessary vapor deposition particles 301 not used for the film formation of the vapor deposition film 302 in the target film forming region 202 can be prevented from entering the mask opening 12, it is not absolutely necessary to provide the side walls 22 in the restriction unit 20.

Furthermore, according to the present embodiment, by forming the cross section of the restriction section 25 in an inverse concave shape as described above, a distance β from the lower face 21a of the top wall 21 to the upper face 30a of the vapor deposition source 30 can be set to the same height as the distance γ2 from the lower face 502a of the restriction section 502 of the restriction unit 20 illustrated in FIG. 18 to the upper face 30a of the vapor deposition source 30 while maintaining a distance α from the lower face 23a of the opening wall 23 as well as the lower face of the side wall 22 to the upper face 30a of the vapor deposition source 30 at the same height as the distance γ1 from the lower face 502a of the restriction section 502 of the restriction unit 20 illustrated in FIGS. 16A and 16B to the upper face 30a of the vapor deposition source 30.

The distance α from the lower face 23a of the opening wall 23 as well as the lower face of the side wall 22 to the upper face 30a of the vapor deposition source 30, particularly the distance α from the lower face 23a of the opening wall 23 to the upper face 30a of the vapor deposition source 30 is not limited to any specific length. However, in the case where the distance α is excessively long like the case of the distance γ2 illustrated in FIG. 18, there arises a possibility that the vapor deposition flow from the adjacent nozzle enters into the restriction opening 24 as illustrated in FIG. 18. Accordingly, it is preferable for the distance α to be not greater than 100 mm, and more preferable to be not greater than 50 mm.

On the other hand, in the case where the distance α is excessively short, the influence of the radiation heat from the vapor deposition source 30, particularly the influence of the radiation heat from the vapor deposition source 30 toward the lower face 23a of the opening wall 23 and the lower face of the side wall 22 becomes large. Accordingly, it is preferable for the distance α to be not less than 1 mm, and more preferable to be not less than 10 mm.

In a case where a shutter (not illustrated) is inserted between the lower face 23a of the opening wall 23 as well as the lower face of the side wall 22 and the upper face 30a of the vapor deposition source 30, specifically between the lower face 23a of the opening wall 23 as well as the lower face of the side wall 22 and the upper face 30a of the vapor deposition source 30 in a range between the vapor deposition source openings 31 adjacent to each other, it is preferable to satisfy a relation of α≥20 mm.

It is sufficient that the lengths in the X-axis and Y-axis directions of the top wall 21 surrounding the respective restriction openings 24 and the length in the Y-axis direction of the opening wall 23 and the side wall 22 are appropriately set in accordance with the sizes of the target film forming region 202 and the non-film forming region 204 in the target film forming substrate 200, the size of the restriction opening 24 corresponding to the size of the target film forming region 202, and the like. Accordingly, these lengths are not limited to any specific values.

### Film Formation Chamber 2

In the film formation chamber 2, in order to keep the inside of the film formation chamber 2 in a vacuum state at the time of vapor deposition, there is provided a vacuum pump (not illustrated) configured to perform vacuum exhaust operation to form a vacuum inside the film formation chamber 2 through an exhaust port (not illustrated) provided in the film formation chamber 2. The control device configured to control actions of the vacuum pump and the vapor deposition device 100 is provided outside the film formation chamber 2. The substrate carrying device 3, the vapor deposition mask 10, the restriction unit 20 and the vapor deposition source 30; and a mask holder, a substrate holder, a deposition preventing member and a shutter (these are not illustrated) are provided inside the film formation chamber 2.

### Substrate Carrying Device 3

The vapor deposition device 100 according to the present embodiment includes at least one of the substrate carrying device 3 and a not illustrated vapor deposition unit carrying device (vapor deposition unit movement device), for example. With this configuration, in the present embodiment, scan vapor deposition is carried out by relatively moving the target film forming substrate 200 and the vapor deposition unit 1 including the vapor deposition mask 10, the restriction unit 20, and the vapor deposition source 30 in such a manner as to make the Y-axis direction be the scanning direction.

FIG. 2 illustrates a case in which the vapor deposition mask 10, the restriction unit 20, and the vapor deposition source 30 are moved as one unit along the scanning direction as discussed above as an example.

The substrate carrying device 3 and the vapor deposition unit carrying device are not limited to any specific devices, and various types of known movement devices such as a roller type movement device and a hydraulic movement device, for example, can be used.

Note that, however, it is sufficient that at least one of the target film forming substrate 200 and the vapor deposition unit 1 is provided in a relatively movable manner. Accordingly, it is also sufficient that at least one of the substrate carrying device 3 and the vapor deposition unit carrying device is provided, and one of the target film forming substrate 200 and the vapor deposition unit 1 may be fixed to the inner wall of the film formation chamber 2 as discussed above.

### Production Method for Vapor Deposition Film

In the present embodiment, the vapor deposition is carried out while at least one of the target film forming substrate 200 and the vapor deposition unit 1 being relatively moved in the Y-axis direction, as discussed above.

A production method for a vapor deposition film according to the present embodiment includes: a disposing process in which the vapor deposition unit 1 and the target film forming substrate 200 are disposed opposing each other and being distanced from each other by a constant distance; an alignment process in which alignment of relative positions of the vapor deposition mask 10 and the target film forming substrate 200 is carried out using alignment markers (not illustrated) provided on the vapor deposition mask 10 and the target film forming substrate 200 respectively, and adjustment of a gap between the vapor deposition mask 10 and the target film forming substrate 200 (gap control) is carried out; and a deposition process in which the vapor deposition particles 301 emitted from the vapor deposition source 30 are deposited on the target film forming substrate 200 through the restriction unit 20 and the vapor deposition mask 10 while relatively moving, in plan view, at least one of the vapor deposition unit 1 and the target film forming substrate 200 in the scanning direction (in other words, the Y-axis direction, which is a direction orthogonal to the X-axis direction in which the restriction openings 24 are arranged).

As the vapor deposition film 302, selective patterning layers (e.g., light emitting layers of respective colors) in an organic EL display device can be cited, for example.

The restriction unit 20 according to the present embodiment, the vapor deposition device 100 using the restriction unit 20, and the production method for the vapor deposition film using the vapor deposition device 100 can be appropriately applied to a production method for an EL element and an EL display device including the stated EL element.

Examples of an EL display device produced by the vapor deposition device 100 and a production method for the stated display device will be described below. Hereinafter, the organic EL display device 400 is cited and described as an example of the above-mentioned EL display device. In the following description, “organic EL display device” can be rephrased as “inorganic EL display device” or “EL display device”. Likewise, “organic EL layer” can be rephrased as “inorganic EL layer” or “EL layer”.

### Schematic Configuration of EL Display Device

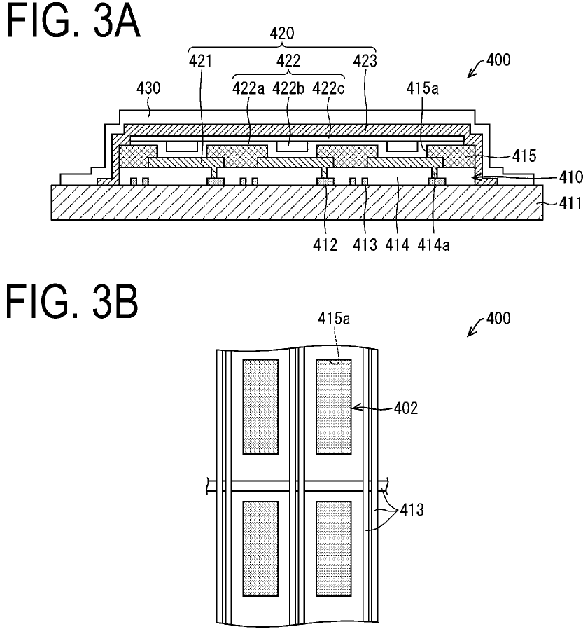

FIG. 3A is a cross-sectional view illustrating an example of a schematic configuration of the organic EL display device 400 produced in the present embodiment, and FIG. 3B is a plan view illustrating a schematic configuration of the sub pixel 402 of the organic EL display device 400 illustrated in FIG. 3A.

As illustrated in FIG. 3A, the organic EL display device 400 has a structure in which an organic EL element 420 and a sealing layer 430 are provided in that order on a Thin Film Transistor (TFT) substrate 410.

The TFT substrate 410 is provided with an insulating substrate 411, as a support substrate, made of a glass substrate, a plastic substrate, or the like. A TFT 412, signal lines 413, an interlayer insulating film 414, and the like are provided on the insulating substrate 411.

The signal lines 413 are configured of a plurality of gate lines, a plurality of source lines, a plurality of power source lines, and the like. In each of regions surrounded by these signal lines 413 in a lattice form, the sub pixels 402 of respective colors are disposed. For example, a set of sub pixels 402 of red (R), green (G), and blue (B) forms one pixel 401 (see FIG. 2).

The sub pixels 402 respectively include the TFTs 412. The TFTs 412 are each connected to the signal lines 413, where the sub pixel 402 to which a signal is inputted is selected by the gate line, an amount of charge to be inputted to the selected sub pixel 402 is determined by the source line, and a current is made to flow into the organic EL element 420 from the power source line.

The TFTs 412 and the signal lines 413 are covered with the interlayer insulating film 414. As a material of the interlayer insulating film 414, an insulative material such as an acrylic resin or a polyimide resin, for example, can be used. It is sufficient for the thickness of the interlayer insulating film 414 to be such that a step on an upper face of the TFT 412 and the signal line 413 can be removed, and thus the thickness thereof is not limited to any specific value.

The organic EL element 420 is configured of a first electrode 421 (positive electrode), an organic EL layer 422, a second electrode 423 (negative electrode), and the like.

The first electrode 421 is formed on the interlayer insulating film 414. The first electrode 421 injects (supplies) holes into the organic EL layer 422, while the second electrode 423 injects electrons into the organic EL layer 422. The first electrode 421 is electrically connected with the TFT 412 via a contact hole 414a formed in the interlayer insulating film 414.

An end portion of the first electrode 421 is covered with an edge cover 415. The edge cover 415 is an insulating layer, and is constituted with a photosensitive resin, for example. The edge cover 415 prevents a short circuit with the second electrode 423 at the end portion of the first electrode 421 due to electrode concentration, the organic EL layer 422 being thinned, or the like. Further, the edge cover 415 also functions as a pixel separation film to prevent the current from being leaked to adjacent sub pixels 402.

An opening 415a is provided in the edge cover 415 for each of the sub pixels 402. An exposed portion of the first electrode 421 by the above opening 415a becomes a light emitting region of each sub pixel 402.

The organic EL layer 422 is provided between the first electrode 421 and the second electrode 423. The organic EL layer 422 has a structure in which, as organic layers, a hole injection and transport layer 422a, a light emitting layer 422b, an electron transport and injection layer 422c, and the like are layered in that order from the first electrode 421 side, for example.

The organic layers other than the light emitting layer 422b are not absolutely necessary layers, and may be appropriately formed in accordance with required characteristics of the organic EL element 420. As such, it is sufficient that the organic EL layer 422 includes the light emitting layer 422b; that is, the organic EL layer 422 may be the light emitting layer 422b itself, or may include the light emitting layer 422b and a layer other than the light emitting layer 422b.

The light emitting layer 422b is a layer having a function to recombine the holes injected from the first electrode 421 side and the electrons injected from the second electrode 423 side so as to emit light. The light emitting layer 422b is formed with a material of high light emitting efficiency such as low molecular weight fluorescent colorant or a metal complex.

Note that, a single layer may have a plurality of functions. For example, the hole injection and transport layer 422a may have a structure in which a hole injecting layer and a hole transport layer are provided as separate layers, or may be a hole injection-cum-transport layer including functions of both the stated layers. Likewise, the electron transport and injection layer 422c may have a structure in which an electron injecting layer and an electron transport layer are provided as separate layers, or may be an electron injection-cum-transport layer including functions of both the stated layers. A carrier blocking layer may be appropriately provided between the respective layers.

Although, in FIG. 3A, the first electrode 421 is taken as a positive electrode (a pattern electrode, a pixel electrode) and the second electrode 423 is taken as a negative electrode (a common electrode), the first electrode 421 may be taken as the negative electrode and the second electrode 423 may be taken as the positive electrode. Note that, however, in this case, the order of the layers constituting the organic EL layer 422 is reversed.

In a case where the organic EL display device 400 is a bottom-emitting type device configured to radiate light from a rear face side of the insulating substrate 411, it is preferable that the second electrode 423 be formed with a reflective electrode material, and that the first electrode 421 be formed with a transparent electrode material being transparent or semi-transparent.

On the other hand, in a case where the organic EL display device 400 is a top-emitting type device configured to radiate light from the sealing layer 430 side, it is preferable that the first electrode 421 be formed with a reflective electrode material, and that the second electrode 423 be formed with a transparent electrode material being transparent or semi-transparent.

The sealing layer 430 is formed on the second electrode 423 to cover the second electrode 423, the organic EL layer 422, the edge cover 415, the interlayer insulating film 414, and the like. An organic layer (not illustrated) may be provided between the second electrode 423 and the sealing layer 430 in order to adjust optical characteristics.

The sealing layer 430 prevents the organic EL element 420 from being degraded by moisture, oxygen, or the like entering from exterior. The sealing layer 430 is constituted of, for example, an inorganic film, a layered film of an inorganic film and an organic film, or the like. As an example, silicon nitride, silicon oxide, or the like can be cited.

The organic EL display device 400 controls a voltage applied across the second electrode 423 and the first electrode 421 through the TFT 412 by a drive circuit (not illustrated), thereby making the light emitting layer 422b emit light so as to perform display.

### Production Method for Organic EL Display Device 400

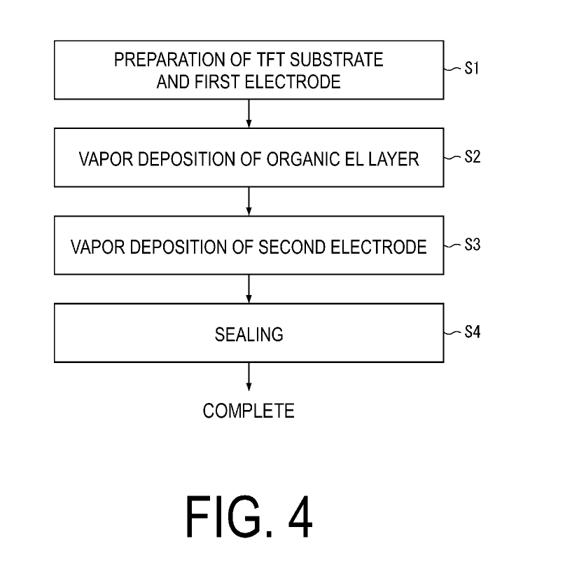

FIG. 4 is a flowchart illustrating production processes of the organic EL display device 400 in the order of the processes to be carried out.

As illustrated in FIG. 4, a production method for the organic EL display device 400 according to the present embodiment includes, roughly speaking, four steps (Ss), namely, a preparation process of a TFT substrate and a first electrode (S1), a vapor deposition process of an organic EL layer (S2), a vapor deposition process of a second electrode (S3), and a sealing process (S4), for example.

Hereinafter, with reference to FIGS. 3A and 3B, an example of each of the above-mentioned processes will be described following the flowchart illustrated in FIG. 4.

First, the TFT 412, the signal line 413, and the like are formed on the insulating substrate 411 by a known method. Next, a photosensitive resin is applied on the insulating substrate 411 to cover the TFT 412 and the signal line 413, and patterning is performed by a photolithographic technique. With this, the interlayer insulating film 414 is formed on the insulating substrate 411.

Next, the contact hole 414a used for electrically connecting the first electrode 421 to the TFT 412 is formed in the interlayer insulating film 414.

Subsequently, the first electrode 421 is formed on the interlayer insulating film 414. The first electrode 421 can be formed as follows: a conductive film (electrode film) is film-formed on the interlayer insulating film 414, photoresist is applied onto the conductive film, and patterning is performed using the photolithographic technique; and thereafter etching is performed on the conductive film and the photoresist is separated.

The sputtering, vacuum vapor deposition technique, CVD, plasma CVD, printing method, or the like can be used for layering the above conductive film.

Hereinafter, a case in which the restriction unit 20 and the vapor deposition device 100 including the restriction unit 20 according to the present embodiment are used at least for the film formation of the light emitting layer 422b of the organic EL layer 422 is cited as an example and explained. However, it goes without saying that the restriction unit 20 and the vapor deposition device 100 according to the present embodiment can be used for the film formation of the above-mentioned conductive film.

Next, the edge cover 415 is formed in a predetermined pattern. Through the above-discussed steps, the TFT substrate 410 and the first electrode 421 are produced (S1).

Next, pressure reduction baking processing for dehydration is performed on the TFT substrate 410 on which the first electrode 421 is formed, and further oxygen plasma processing is performed for surface washing of the first electrode 421.

Thereafter, the organic EL layer 422 including the light emitting layer 422b is film-formed on the TFT substrate 410 (S2).

The ink-jet method, printing method, vacuum vapor deposition technique, CVD, plasma CVD, or the like can be used for the film formation of the organic EL layer 422. In the present embodiment, as described above, the production method for the vapor deposition film using the restriction unit 20 and the vapor deposition device 100 is applied at least to the film formation of the light emitting layer 422b of the organic EL layer 422. The production method for the vapor deposition film using the restriction unit 20 and the vapor deposition device 100 may be applied to the film formation of the hole injection and transport layer 422a, the electron transport and injection layer 422c, and the like, by changing the mask pattern shape of the vapor deposition mask 10.

In the present embodiment, a vapor deposition process of the hole injection and transport layer (S11), a vapor deposition process of the light emitting layer (S12), and a vapor deposition process of the electron transport and injection layer (S13) are carried out in that order as the vapor deposition process of the organic EL layer (S2). In other words, the vapor deposition process of the organic EL layer (S2) according to the present embodiment may include the vapor deposition process of the hole injection and transport layer (S11), the vapor deposition process of the light emitting layer (S12), and the vapor deposition process of the electron transport and injection layer (S13). Note that the order of the steps (processes) indicated by S11 to S13 mentioned above is reversed in a case where the first electrode 421 is taken as a negative electrode and the second electrode 423 is taken as a positive electrode. In a case of the organic EL layer 422 being formed of the light emitting layer 422b, the vapor deposition process of the organic EL layer (S2) refers to the vapor deposition process of the light emitting layer (S12).

In the vapor deposition process of the organic EL layer (S2), the above-described production method for the vapor deposition film according to the present embodiment is applied at least in the vapor deposition process of the light emitting layer (S12). In other words, in the present embodiment, at least the light emitting layer 422b of each of the sub pixels 402 is produced (film-formed) by the production method for the vapor deposition film according to the present embodiment.

Because of this, at least the vapor deposition process of the light emitting layer (S12) includes, for example, the aforementioned alignment process and deposition process. Also, in the processes other than the vapor deposition process of the light emitting layer (S12), it goes without saying that the process to which the production method for the vapor deposition film according to the present embodiment is applied includes the aforementioned alignment process and deposition process.

In the vapor deposition process of the organic EL layer (S2), the TFT substrate 410 on which the first electrode 421 and the edge cover 415 prepared in the preparation process of the TFT substrate and the first electrode (S1) are formed, is used as the target film forming substrate 200. In other words, in the vapor deposition process of the organic EL layer (S2), used is the target film forming substrate 200 where, as one of the pair of electrodes prepared at both sides of the light emitting layer 422b, the first electrode 421 is provided beforehand in the target film forming region 202. At this time, by using a mother substrate, as the target film forming substrate 200, in which a plurality of target film forming regions 202 to become formation regions of the organic EL display devices 400 are provided and from which the plurality of organic EL display devices 400 can be cut out, a production method supporting the mass production process can be realized. In the case of using a mother substrate for the target film forming substrate 200, after the sealing process (S4), a partitioning process (S5, an organic EL display device cutout process, not illustrated) is additionally carried out in which the plurality of organic EL display devices 400 are cut out from the mother substrate by partitioning the stated mother substrate.

In FIGS. 3A and 3B, a case in which the light emitting layer 422b is vapor-deposited selectively patterned for each light emission color so as to perform full color display is cited and illustrated as an example. However, a scheme in which the organic EL element 420 configured to emit white (W) color light using the light emitting layer 422b emitting white color light and a color filter (CF) layer (not illustrated) are combined so as to select light emission color in each sub pixel 402, a scheme in which the light emitting layer 422b emitting W color light is used and a micro cavity structure is introduced to each of the sub pixels 402 so as to realize image display of full color, or the like may be employed. In the case where light emission color of each of the sub pixels 402 is changed by a method such as the CF layer or the micro cavity structure, the light emitting layer 422b need not be selectively patterned for each sub pixel 402.

Next, the second electrode 423 is formed across the whole display region of the TFT substrate 410 in such a manner as to cover the organic EL layer 422 (S3).

The second electrode 423 can be formed by the same method as that of the hole injection and transport layer 422a, the electron transport and injection layer 422c, or the like, for example. Accordingly, the restriction unit 20 and the vapor deposition device 100 can also be used for the film formation of the second electrode 423.

By the method discussed above, the organic EL element 420 formed of the first electrode 421, the organic EL layer 422, and the second electrode 423 can be formed on the TFT substrate 410.

Thereafter, the sealing layer 430 is formed on the second electrode 423 to cover the second electrode 423. The sputtering, vacuum vapor deposition technique, CVD, plasma CVD, printing method, or the like can be used for forming the sealing layer 430 in a case of the sealing layer 430 being a sealing film. In the case of the sealing layer 430 being a sealing film, the restriction unit 20 and the vapor deposition device 100 according to the present embodiment may be used for the film formation of the sealing layer 430.

The sealing layer 430 may be a sealing substrate made of an insulating substrate such as a glass substrate or a plastic substrate. In this case, an insulating substrate having substantially the same size as the insulating substrate 411 may be used for the sealing layer 430, and the partitioning may be performed, after having sealed the organic EL element 420, in accordance with the size of the target organic EL display device 400. Indented glass may be used as a sealing substrate, and the sealing layer 430 may be formed by performing sealing in a frame shape using a sealing resin, frit glass, or the like. Alternatively, the sealing layer 430 made of a sealing substrate and a resin may be formed by filling the resin between the TFT substrate 410 and the sealing substrate.

As discussed thus far, in the production processes of the organic EL display device 400 according to the present embodiment, it is sufficient that at least any one of the vapor deposition process of the organic EL layer (S2), the vapor deposition process of the second electrode (S3), and the sealing process (S4) includes the aforementioned alignment process and deposition process. Further, it is sufficient for the organic EL display device 400 according to the present embodiment to include a pattern of the vapor deposition film 302 formed with the vapor deposition particles 301 having passed through the restriction opening 24 of the restriction unit 20.

However, because the vapor deposition process of the light-emitting layer (S12) includes the alignment process and the deposition process, the light emitting layer 422b having a high resolution pattern without a pattern blur, a color mix, or the like due to the adhesion of the tiny film 304 (see FIG. 18) can be formed. Because of this, it is preferable that at least the vapor deposition process of the light emitting layer (S12) include the alignment process and the deposition process. With this, an EL display device, such as the organic EL display device 400, having higher display quality than the existing display device can be provided.

### Advantageous Effects

FIG. 5 is a cross-sectional view illustrating an example of an effect by the restriction unit 20 according to the present embodiment.

According to the present embodiment, as illustrated in FIG. 5, by forming a cross section of the restriction section 25 in an inverse concave shape, of a face of the restriction section 25 opposing the vapor deposition source 30 (that is, the lower face of the restriction section 25), a portion other than the face of the opening wall 23 and the side wall 22 opposing the vapor deposition source 30 (that is, the lower face 21a of the top wall 21) can be distanced from the vapor deposition source 30. According to the present embodiment, it is possible to substantially distance the restriction section 25 from the vapor deposition source 30 without degrading an original function of the restriction unit 20 to control the isotropic vapor deposition flow and enhance the directivity.

As such, according to the present embodiment, because the radiation heat from the vapor deposition source 30 toward the restriction section 25 can be reduced and the temperature of the lower face of the restriction section 25 can be lowered, the re-evaporation of the vapor deposition objects 303 adhering to the restriction section 25 can be reduced. As a result, abnormal film formation like the tiny film 304 can be prevented because re-adhesion of the vapor deposition objects 303 to the vapor deposition source 30 caused by the re-evaporation of the vapor deposition objects 303 having adhered to the restriction section 25 can be suppressed or prevented.

A side surface of each of the opening wall 23 and the side wall 22, in other words, a Z-Y plane of the restriction section 25 is not heated to a high temperature in comparison with the lower face of restriction section 25, so that the amount of re-evaporation is physically small. In reality, significant amounts of re-evaporation from the side surfaces of the opening wall 23 and the side wall 22 were not observed in experiment using an actual device, and as illustrated in FIG. 5, the re-adhesion of the vapor deposition objects 303 as illustrated in FIG. 16B and FIG. 18 was not observed on the upper face 30a of the vapor deposition source 30.

According to the present embodiment, it is possible to provide an EL display device, such as the organic EL display device 400, that includes a high resolution pattern without the adhesion of the tiny film 304, and exhibits higher display quality than the existing display device.

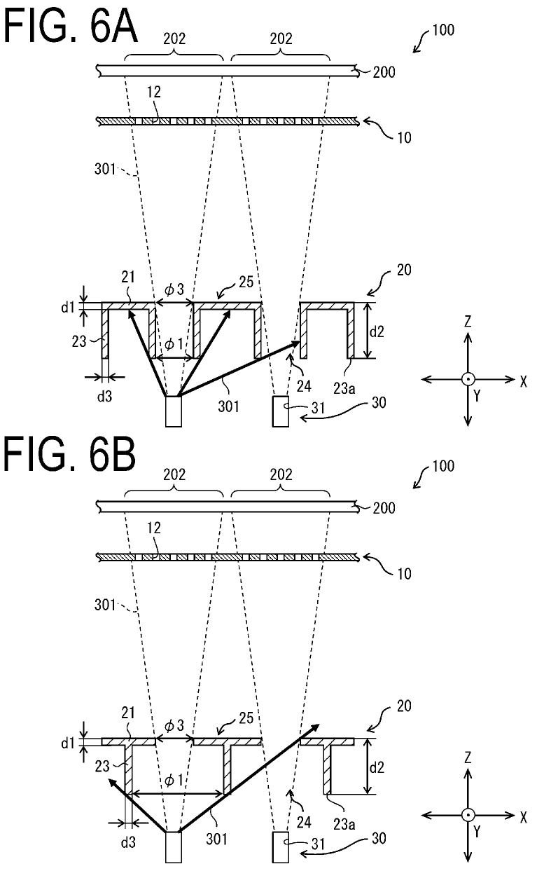

FIGS. 6A and 6B are cross-sectional views illustrating an example of an effect by the restriction unit 20 according to the present embodiment compared to a case in which a cross-sectional shape of a cross section parallel to the X-axis direction of the restriction section 25 has a T shape. FIG. 6A schematically illustrates a main portion of the vapor deposition device 100 according to the present embodiment. Meanwhile, FIG. 6B is a comparative example in which the configuration of a main portion of the vapor deposition device 100 is schematically illustrated when the cross section of the restriction section 25 of the restriction unit 20 of the vapor deposition device 100 illustrated in FIG. 6A is formed in a T shape.

An equation of d1=d3 holds in each restriction unit 20 illustrated in FIGS. 6A and 6B, and a relation of d1<d2 is satisfied therein.

In the restriction unit 20 of FIG. 6A, an opening width ϕ1 in the X-axis direction at a lower portion of the restriction opening 24 (that is, on the vapor deposition source 30 side) is equal to an opening width ϕ3 in the X-axis direction at an upper portion of the restriction opening 24 (that is, on the vapor deposition mask 10 side). As such, in the restriction unit 20 illustrated in FIG. 6A, a film formation range in the X-axis direction on the target film forming substrate 200 (in other words, size of the target film forming region 202 in the X-axis direction) brought by the vapor deposition flow is determined by the opening width ϕ3 in the X-axis direction at the upper portion of the restriction opening 24. On the other hand, an unnecessary vapor deposition flow is cut (captured) in the lower face of the restriction section 25.

As illustrated in FIG. 6A, in the case where the cross section of the restriction section 25 is formed in an inverse concave shape, the lower face 23a of the opening wall 23 is present near the vapor deposition source opening 31. Due to this, as indicated by arrow marks in FIG. 6A, even in a case where the vapor deposition particles 301 emitted from the vapor deposition source opening 31 pass under the restriction section 25 surrounding the restriction opening 24 corresponding to the above vapor deposition source opening 31 and scatter toward the target film forming region 202 adjacent to the target film forming region 202 corresponding to the above restriction opening 24, in other words, toward the target film forming region 202 other than the target film forming region 202 corresponding to the above restriction opening 24 (called an “adjacent target film forming region” below), such vapor deposition particles are cut (captured) by the restriction section 25 adjacent to the restriction section 25 surrounding the above-mentioned restriction opening 24 (called an “adjacent restriction section” below). As such, in this case, the vapor deposition particles 301 can be prevented from flying to the adjacent target film forming region on the target film forming substrate 200.

Meanwhile, as illustrated in FIG. 6B, in the case where the cross section of the restriction section 25 is formed in a T shape, the opening width ϕ3 in the X-axis direction at the upper portion of the restriction opening 24 is smaller than the opening width ϕ1 in the X-axis direction at the lower portion of the restriction opening 24. Due to this, in the case where the cross section of the restriction section 25 is formed in a T shape, the size in the X-axis direction of the target film forming region 202 is determined by the opening width ϕ3 in the X-axis direction at the upper portion of the restriction opening 24 and the unnecessary vapor deposition flow is cut (captured) in the lower face of the restriction section 25. However, the lower face 23a of the opening wall 23 is not present near the vapor deposition source opening 31. As such, in this case, as indicated by arrows in FIG. 6B, there is a possibility that the vapor deposition particles 301 emitted from the vapor deposition source opening 31 are not cut by the adjacent restriction section and travel toward the adjacent target film forming region.

Further, in the case where the cross section of the restriction section 25 is formed in a T shape, since the lower face 23a of the opening wall 23 is not present near the vapor deposition source opening 31, a physical nozzle length of each of the restriction openings 24 is substantially equal to the thickness d1 of the top wall 21. As such, in the case where the cross section of the restriction section 25 is formed in an inverse concave shape, the physical nozzle length of each of the restriction openings 24 is longer than that in the case where the cross section of the restriction section 25 is formed in a T shape. Because of this, in the case where the cross section of the restriction section 25 is formed in an inverse concave shape, an effect of improvement in collimator properties of the vapor deposition particles 301 is enhanced in comparison with the case where the cross section of the restriction section 25 is formed in a T shape.

### First Modification

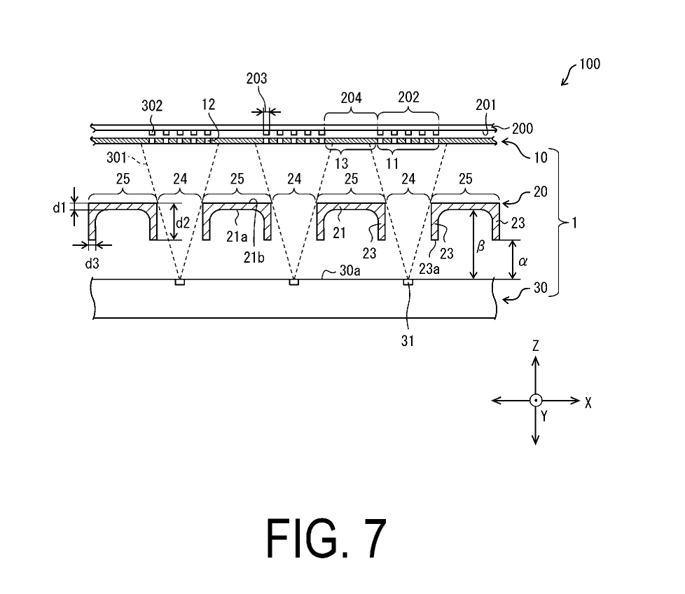

FIG. 7 is a cross-sectional view illustrating a schematic configuration of a main portion of the vapor deposition device 100 according to a first modification on the first embodiment.

In the present embodiment, as illustrated in FIG. 1, for example, the case in which, in each of the restriction sections 25 of the restriction unit 20, the thicknesses of the top wall 21 and the opening wall 23 are uniform and are the same in size and the opening wall 23 has a shape vertically hung in the vertical direction (vertically provided downward) from the top wall 21 is cited as an example and explained. However, the present embodiment is not limited thereto.

It is not absolutely necessary for the top wall 21 and the opening wall 23 to have uniform thicknesses, and they may have different thicknesses from each other. Accordingly, as illustrated in FIG. 7, each of the restriction sections 25 of the restriction unit 20 may have a shape in which the lower face 21a of the top wall 21 is round (curved shape), for example. In this case, when a thickness of a center portion of the top wall 21 is taken as d1 and a length in the X-axis direction of the lower face 23a of the opening wall 23 is taken as d3 in each restriction section 25, the thickness d1 and the length d3 can be designed in the same manner as in the case of the restriction unit 20 illustrated in FIG. 1.

As discussed above, it is sufficient that each restriction section 25 of the restriction unit 20 according to the present embodiment has a cross-sectional shape of an inverse concave with the base open, in other words, a shape in which the base surface is recessed toward the inner side.

### Second Modification

Further, in the present embodiment, although the case in which the restriction unit 20 includes the plurality of restriction openings 24 arranged in the X-axis direction is cited as an example and explained, the present embodiment is not limited thereto. It is sufficient that the restriction unit 20 includes at least one restriction opening 24 and is provided with the plurality of restriction sections 25, prepared at both sides of the restriction opening 24, each having the top wall 21 and vertical walls including the opening walls 23, and that these restriction sections 25 have a cross-sectional shape of an inverse concave as discussed above. Even in a case where only one target film forming region 202 is provided on the target film forming substrate 200 and only one restriction opening 24 is provided, the above-described effect can be obtained.

### Third Modification

Furthermore, in the present embodiment, the case in which a line vapor deposition source including the plurality of vapor deposition source openings 31 (nozzle section) in the X-axis direction is used for the vapor deposition source 30, is cited as an example and explained. However, as discussed above, in the case where there is provided only one restriction opening 24, it is sufficient for the vapor deposition source 30 to include one vapor deposition source opening 31.

### Fourth Modification

For example, as illustrated in FIG. 6A, it is also possible to arrange a plurality of vapor deposition sources each including one vapor deposition source opening 31 in the X-axis direction and use them in place of the line vapor deposition source.

### Fifth Modification

Moreover, the restriction unit 20, the vapor deposition unit 1, and the vapor deposition device 100 according to the present embodiment can be appropriately used for the scan vapor deposition as discussed above. However, the present embodiment is not limited thereto. The restriction unit 20, the vapor deposition unit 1, and the vapor deposition device 100 can be appropriately used in the following: (1) a method in which vapor deposition is performed while fixing each of positional relationships among the target film forming substrate 200, the vapor deposition mask 10, the restriction unit 20, and the vapor deposition source 30, (2) vapor deposition in which film formation is performed by sequentially moving the vapor deposition mask 10 relative to the target film forming substrate 200 and causing the mask to adhere (contact) for each movement, or the like. Even in the case of using the restriction unit 20 in this type of vapor deposition scheme, the use of the restriction unit 20 makes it possible to improve at least film thickness distribution in the X-axis direction and achieve the above-mentioned effect.

### Second Embodiment

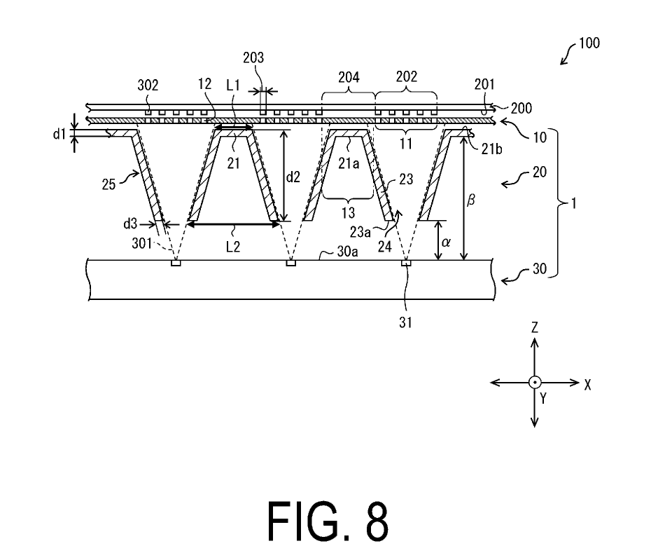

A description follows regarding a second embodiment, with reference to FIGS. 8 to 13. The present embodiment will be stated by the differences between the present embodiment and the first embodiment, and components having the same functions as the components used in the first embodiment are appended with the same reference signs, and the description thereof is omitted.

In FIG. 8 to FIG. 13, for the sake of convenience in illustration in the present embodiment as well, the numbers of mask openings 12 and restriction openings 24, the numbers of target film forming regions 202 and target film forming pattern regions 203, and the like are reduced in the drawings.

### Schematic Configuration of Vapor Deposition Device 100

FIG. 8 is a cross-sectional view illustrating a schematic configuration of a main portion of the vapor deposition device 100 according to the present embodiment.

As illustrated in FIG. 8, the vapor deposition device 100 according to the present embodiment is the same as the vapor deposition device 100 according to the first embodiment except for a point that the opening wall 23 of the restriction unit 20 is slanted relative to a normal direction of the top wall 21.

As illustrated in FIG. 8, the opening wall 23 of the restriction unit 20 according to the present embodiment is vertically provided downward (vertically hung) from the top wall 21 to spread toward an outer side relative to the normal direction of the top wall 21, in other words, toward the vapor deposition source opening 31.

As such, in the present embodiment, each of the restriction sections 25 has a cross-sectional shape of an inverse concave in which the opening walls 23 prepared at both sides of the top wall 21 are slanted to spread toward the outer side relative to the normal direction of the top wall 21 (in other words, a reversely tapered cross-sectional shape in which the top wall 21 side is narrower than the vapor deposition source 30 side). That is to say, in the present embodiment, the cross-sectional shape of each restriction section 25 is changed from a general rectangular parallelepiped shape illustrated in FIGS. 16A and 16B to a trapezoidal shape with a vacant interior without the base (that is, with the base open) as illustrated in FIG. 8.

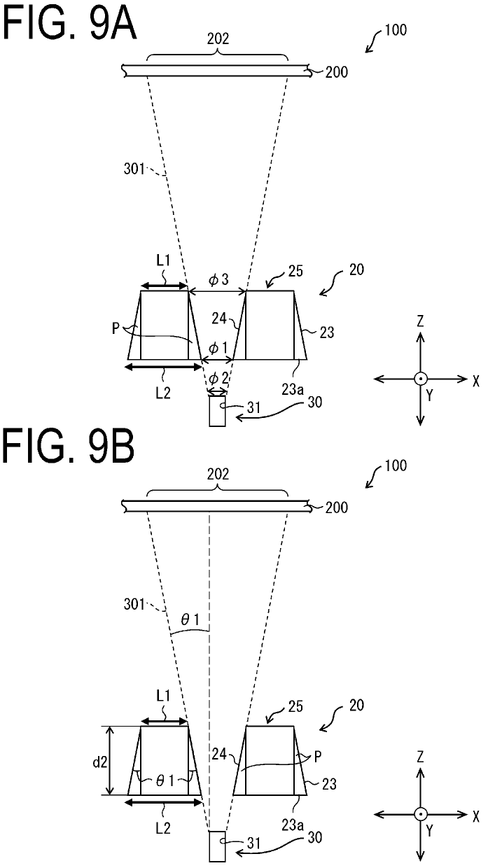

Hereinafter, design of the restriction unit 20 according to the present embodiment will be described additionally referring to FIGS. 9A and 9B to FIG. 12.

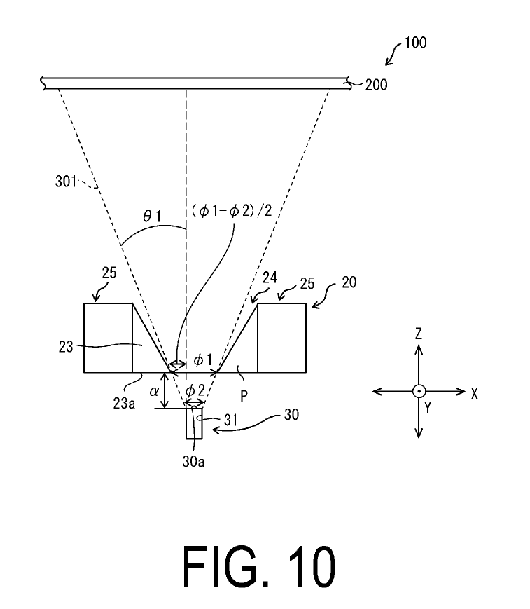

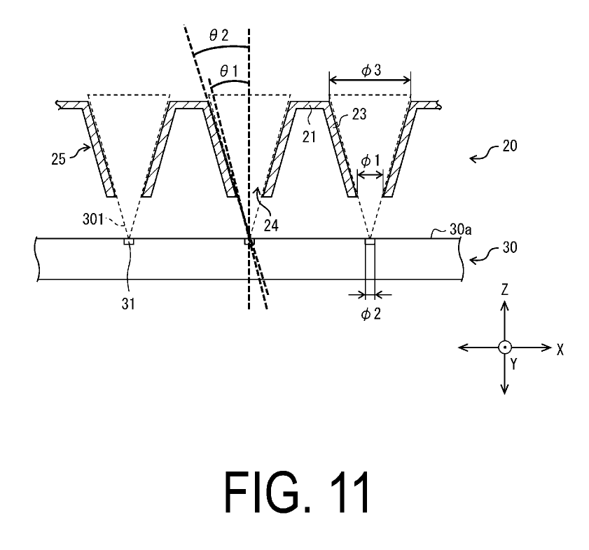

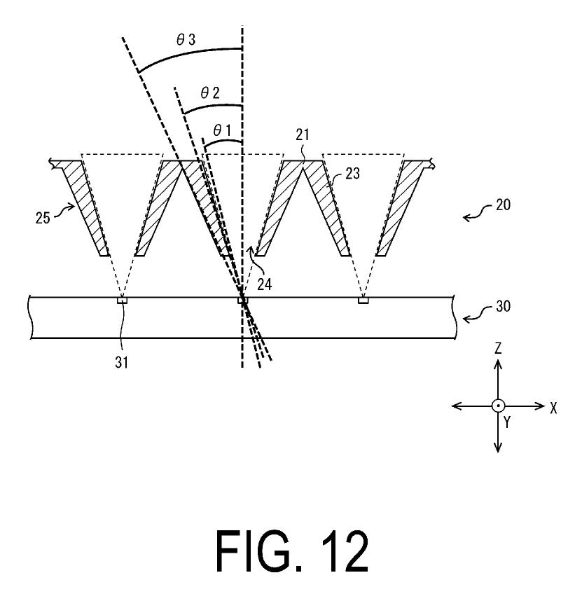

FIGS. 9A and 9B are cross-sectional views each schematically illustrating the configuration of a main portion of the vapor deposition device 100 according to the present embodiment, in order to explain the design of the restriction unit 20 according to the present embodiment. Note that the vapor deposition mask 10 is not illustrated in FIGS. 9A and 9B. FIG. 10 is a cross-sectional view explaining a vapor deposition angle θ1 of the vapor deposition device according to the present embodiment. FIG. 11 is a cross-sectional view explaining a taper angle of the opening wall 23 of the restriction unit 20 according to the present embodiment. FIG. 12 is another cross-sectional view explaining the taper angle of the opening wall 23 of the restriction unit 20 according to the present embodiment.

As discussed above, each of the restriction sections 25 of the restriction unit 20 according to the present embodiment has a cross section formed in a trapezoidal shape with a vacant interior. Because of this, as illustrated in FIG. 8 and FIGS. 9A and 9B, a length L1 in the X-axis direction of the top wall 21 in each restriction section 25, to be more specific, a length L1 in the X-axis direction of the top wall 21 interposed between the restriction openings 24 adjacent to each other is shorter than a length L2 in the X-axis direction of an outer shape of each of the restriction sections 25 in plan view.

Accordingly, in the restriction unit 20, as illustrated in FIGS. 9A and 9B, an opening width ϕ1 in the X-axis direction at the lower portion of the restriction opening 24 is smaller than an opening width ϕ3 in the X-axis direction at the upper portion of the restriction opening 24. Because of this, in the present embodiment, the size in the X-axis direction of the target film forming region 202 is determined by the opening width ϕ1 in the X-axis direction at the lower portion of the restriction opening 24. In the present embodiment, the size in the X-axis direction of the restriction opening 24 on the vapor deposition source 30 side (the above opening width ϕ1) is smaller than the size in the X-axis direction of the restriction plate opening 501 of the restriction unit 500 with the cross section of the restriction section 502 being a cross-sectional shape of a general rectangular parallelepiped as illustrated in FIGS. 16A and 16B, and is also smaller than the size in the X-axis direction of the restriction opening 24 of the restriction unit 20 (opening width ϕ1) in the first embodiment.

Here, in the present embodiment, the length L1 can be rephrased as a distance between opening ends on the top wall 21 side of the opening walls 23 adjacent to each other in the X-axis direction in each of the restriction sections 25, that is, a distance between the opening ends of the opening walls 23 adjacent to each other in the X-axis direction on a face of each restriction section 25 opposing the vapor deposition mask 10. Further, the length L2 can be rephrased as a distance between the opening ends of the opening walls 23 adjacent to each other in the X-axis direction on a surface of each restriction section 25 opposing the vapor deposition source 30. To be more specific, in a case where an outer shape of a cross section of each of the restriction sections 25 parallel to the X-axis direction is taken as a trapezoid, the length L1 indicates the length of the upper base of the trapezoid, and the length L2 indicates the length of the lower base of the trapezoid.

Neither L1 nor L2 is limited to any specific value as long as a relation of L1<L2 is satisfied. Note that the opening width ϕ1 and the length L2 in the X-axis direction of the outer shape of each restriction section 25 in plan view are determined by the vapor deposition angle θ1 with respect to the target film forming region 202 in such a manner as for the vapor deposition film 302 to be formed across the whole of each target film forming region 202 in the X-axis direction. Preferable design of the restriction unit 20 will be described below.

A range in the X-axis direction of the vapor deposition flow in the case where the outer shape of the cross section of each of the restriction sections 25 has a cross-sectional shape of a rectangular parallelepiped, in other words, the size in the X-axis direction of the target film forming region 202 brought by the above vapor deposition flow is determined by the opening width ϕ3 in the X-axis direction at the upper portion of restriction opening 24.

Here, the case where the outer shape of the cross section of each of the restriction sections 25 has a cross-sectional shape of a rectangular parallelepiped refers to a case where the restriction sections 25 have a cross-sectional shape of a square with one side open in which the opening walls 23 are vertically hung in the vertical direction (vertically provided downward) from the top wall 21 like in the first embodiment, or a case where each restriction section is made of a plate called a restriction plate like in the known technique. In other words, in the present embodiment, the outer shape of the cross section of each restriction section 25 refers to a shape connecting the base in the case where the base of each restriction section 25 is open (that is, a shape connecting the lower faces 23a of the opening walls 23 of the restriction section 25, for example).

As illustrated in FIGS. 9A and 9B, in the case where the cross section of each of the restriction sections 25 is formed in a trapezoidal shape with a vacant interior without the base (in other words, in the case where the outer shape of the cross section of each restriction section 25 takes a trapezoidal shape), in order to maintain substantially the same size in the X-axis direction of the vapor deposition flow as in the case of the outer shape of the cross section of each restriction section 25 taking a cross-sectional shape of a rectangular parallelepiped, the length L2 needs to fall within a range of L2≤L1+ϕ3−ϕ1, where L1 represents the length in the X-axis direction of the top wall 21 of each restriction sections 25, in other words, an outer edge in the X-axis direction of the lower face 23a of the opening wall 23 needs to fall within a range indicated by a triangular hatched portion P on the periphery of the restriction section 25 whose outer shape of the cross section takes a cross-sectional shape of a rectangular parallelepiped as illustrated in FIGS. 9A and 9B.

When the length L2 exceeds the above-mentioned range (in other words, when the outer edge in the X-axis direction of the lower face 23a of the opening wall 23 exceeds the above hatched portion P), an available vapor deposition range becomes smaller than a vapor deposition range in the case of the outer shape of the cross section of each restriction section 25 taking a cross-sectional shape of a rectangular parallelepiped. Therefore, it is advisable for the length L2 to be set within the above-mentioned range. Further, in order to enhance, to the maximum, the effect of cutting an unnecessary vapor deposition flow under the restriction section 25, it is more preferable that the length L2 be given by an equation of L2=L1+ϕ3−ϕ1 (in other words, the outer edge in the X-axis direction of the lower face 23a of the opening wall 23 be positioned at an end portion on the restriction opening 24 side in the hatched portion P).

Like in the first embodiment, in the case where the height of the opening wall 23 (that is, the height in the Z-axis direction of the opening wall 23 and a distance in the Z-axis direction from the upper face 21b of the top wall 21 to the lower face 23a of the opening wall 23) is taken as d2, a preferable value of L2 is indicated by an equation of L2=L1+2*d2*tan θ1.

Further, as illustrated in FIG. 8, in the case where a distance from the lower face 21a of the top wall 21 to the upper face 30a of the vapor deposition source 30 is taken as (3, and a distance from the lower face 23a of the opening wall 23 as well as the lower face of the side wall 22 to the upper face 30a of the vapor deposition source 30 is taken as α, the height d2 of the opening wall 23 is represented by an equation of d2=β+d1−α.

The vapor deposition angle θ1 is determined from the opening width ϕ1 of the restriction opening 24, the size in the X-axis direction of the vapor deposition source opening 31 (nozzle diameter ϕ2), and the distance α from the lower face 23a of the opening wall 23 to the upper face 30a of the vapor deposition source 30.

As can be understood from FIG. 10, an equation of tan θ1=(ϕ1−ϕ2)/2α holds. Accordingly, the vapor deposition angle θ1 can be indicated by an equation of θ1=arctan ((ϕ1−ϕ2)/2α).

Further, as illustrated in FIG. 11, it is preferable that the lengths L1 and L2 be set so that, for example, a taper angle of the opening wall 23 as a longitudinal plate of the restriction section 25, particularly a taper angle θ2 of a face (upper face) of the opening wall 23 facing the restriction opening 24 (that is, a taper angle of an outer side of a trapezoid forming the restriction section 25) becomes larger than the vapor deposition angle θ1.

In the case where the taper angle θ2 is smaller than the vapor deposition angle θ1, there is a possibility that the vapor deposition flow restricted at the entrance of the restriction opening 24 on the vapor deposition source 30 side (in other words, at the opening on the lower face side of the restriction unit 20) is cut (blocked, captured) at the upper face of the opening wall 23 of the restriction section 25.

Further, it is ideal that a taper angle θ3 (see FIG. 12) of a face of the opening wall 23 on the opposite side to the face thereof facing the restriction opening 24 (in other words, a taper angle of a face on an inner side of the trapezoid forming the restriction section 25) is equal to the taper angle θ2.

That is to say, it is preferable that, as illustrated in FIGS. 8 and 11, the opening wall 23 have a uniform thickness, and that a face of the opening wall 23 on the opposite side to the face thereof facing the restriction opening 24 (in other words, a face on the inner side of the trapezoid forming the restriction section 25) be parallel to the face facing the restriction opening 24.

However, the present embodiment is not limited thereto, and the taper angle θ3 may be larger than the taper angle θ2 as illustrated in FIG. 12. In other words, the thickness of the opening wall 23 may be formed to be larger toward the top wall 21 side.

Also, in the present embodiment, the thickness d1 of the top wall 21, the height d2 of the side wall 22 and the opening wall 23, the thickness d3 of the opening wall 23 and the side wall 22, the distance α, and the distance β(β=α+d2) can be set in the same manner as in the first embodiment.

### Advantageous Effects

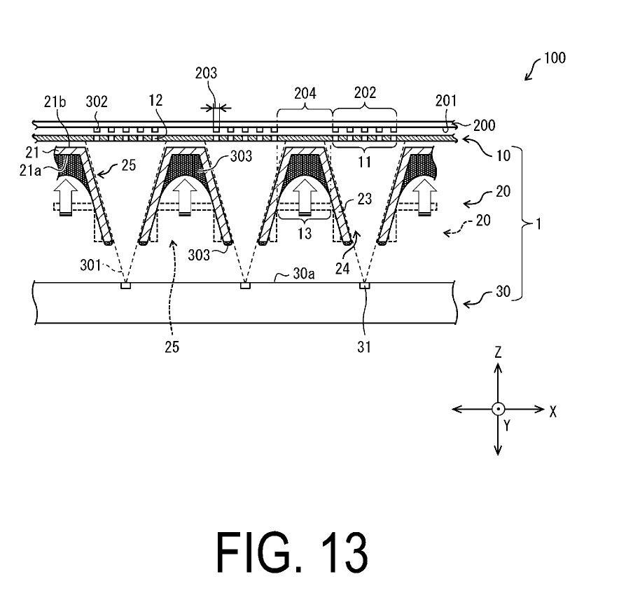

FIG. 13 is a cross-sectional view illustrating an effect by the restriction unit 20 according to the present embodiment.

According to the present embodiment, by the restriction section 25 having a reversely tapered cross-sectional shape as described above, the lower face 21a of the top wall 21, to which the vapor deposition objects 303 adhere most, can be distanced from the vapor deposition source 30, as indicated by a dotted line in FIG. 13, in comparison with a case in which each of the restriction sections 25 has a cross-sectional shape of a square with one side on the base side being open where the opening wall 23 is vertically hung (vertically provided downward) in the vertical direction from the top wall 21 like in the first embodiment. This makes it possible to further decrease the temperature of an adhesion portion of the vapor deposition objects 303 in the restriction unit 20 compared to the first embodiment. Accordingly, the present embodiment makes it possible to further enhance the effect of reduction in the re-adhesion of the vapor deposition objects 303 to the upper face 30a of the vapor deposition source 30 compared to the first embodiment.

### Third Embodiment

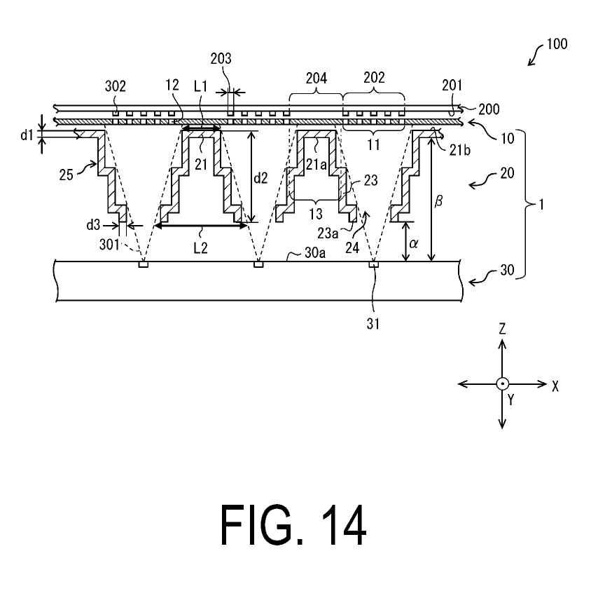

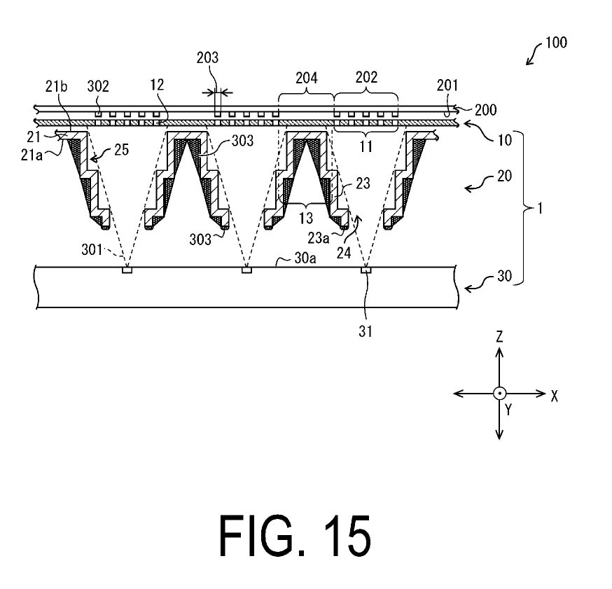

A description follows regarding a third embodiment, with reference to FIGS. 14 and 15. The present embodiment will be stated by the differences between the present embodiment and the first and second embodiments. Components having the same functions as the components used in the first and second embodiments are appended with the same reference signs, and the description thereof is omitted.

Also, in the present embodiment, for the sake of convenience in illustration in FIGS. 14 and 15, the numbers of mask openings 12 and restriction openings 24, the numbers of target film forming regions 202 and target film forming pattern regions 203, and the like are reduced in the drawings.

### Schematic Configuration of Vapor Deposition Device 100

FIG. 14 is a cross-sectional view illustrating a schematic configuration of a main portion of the vapor deposition device 100 according to the present embodiment.

As illustrated in FIG. 14, the vapor deposition device 100 according to the present embodiment is the same as the vapor deposition device 100 according to the second embodiment except for a point that the opening wall 23 of the restriction unit 20 is formed stepwise.

Neither the height of each step of the opening wall 23 nor the number of steps thereof is limited to any specific value in the present embodiment. In FIG. 14, a case in which the number of steps of the opening wall 23 is three is cited as an example and illustrated. However, it is sufficient for the number of steps to be not less than two, and the number thereof may be two or may be not less than four.

Also in the present embodiment, the thickness d1 of the top wall 21, the height d2 of the side wall 22 and the opening wall 23, the thickness d3 of the opening wall 23 and the side wall 22, the distance α, and the distance β (β=α+d2) can be set in the same manner as in the first and second embodiments.

### Advantageous Effects

FIG. 15 is a diagram illustrating an effect by the restriction unit 20 according to the present embodiment.

Also, in the present embodiment, by the restriction section 25 having a reversely tapered cross-sectional shape like in the second embodiment, the lower face 21a of the top wall 21, to which the vapor deposition objects 303 adhere most, can be distanced from the vapor deposition source 30 in comparison with the first embodiment, as illustrated in FIG. 15. Accordingly, the present embodiment can also obtain similar advantageous effects to those of the second embodiment.

Further, according to the present embodiment, since the opening wall 23 is formed stepwise, in other words, formed in a multi-step rectangular shape, the restriction section 25 can be processed with ease. Furthermore, since the height, width, or the like of each step can be appropriately changed, versatility is further enhanced compared to the second embodiment.

### Supplement

The restriction unit 20 according to a first aspect of the present invention is a restriction unit that is configured to restrict the passage of the vapor deposition particles 301 emitted from the vapor deposition source 30 and includes at least one opening (restriction opening 24) configured to allow the vapor deposition particles 301 to pass through and a plurality of non-openings (restriction sections 25) prepared at both sides of the above opening, wherein the non-opening has a cross-sectional shape of an inverse concave formed of the top wall 21 and the opening walls 23.

Because of this, the non-opening has a cross-sectional shape in which the thickness d1 of the top wall 21 is smaller than the height d2 of the opening wall 23 in the non-opening, no base wall is provided, and the base of the non-opening is open.

As such, according to the above configuration, the height d2 of the opening wall 23 that determines a nozzle length of the restriction opening 24 makes it possible to distance most part of a face of the non-opening opposing the vapor deposition source 30, particularly the lower face 21a of the top wall 21, to which the vapor deposition objects 303 adhere most, from the vapor deposition source 30 while the height d2 maintaining a range defined by design.

Accordingly, the above configuration makes it possible to substantially distance the non-opening from the vapor deposition source 30 without degrading an original function of the restriction unit 20 to control the isotropic vapor deposition flow and enhance the directivity.

As such, with the above configuration, because the radiation heat from the vapor deposition source 30 toward the non-opening can be reduced and the temperature of the adhesion portion of the vapor deposition objects 303 in the non-opening can be lowered, the re-evaporation of the vapor deposition objects 303 adhering to the non-opening can be reduced. As a result, according to the above configuration, abnormal film formation like the tiny film 304 can be prevented because the re-adhesion of the vapor deposition objects 303 to the vapor deposition source 30 caused by the re-evaporation of the vapor deposition objects 303 having adhered to the non-opening can be suppressed or prevented. Accordingly, the vapor deposition film 302 of a high resolution pattern without the adhesion of the tiny film 304 due to the re-evaporation of the vapor deposition objects 303, can be produced (film-formed).

The restriction unit 20 according to a second aspect of the present invention is such that, in the first aspect, the opening wall 23 may be provided in parallel to a normal direction of the top wall 21.

According to the above configuration, an effect described in the first aspect can be obtained with a simple configuration.

The restriction unit 20 according to a third aspect of the present invention is such that, in the first aspect, the opening wall 23 may be provided being slanted relative to the normal direction of the top wall 21, and the non-opening may have a reversely tapered cross-sectional shape smaller in size on the top wall 21 side than on the vapor deposition source 30 side.

The above configuration makes it possible to distance the lower face 21a of the top wall 21, to which the vapor deposition objects 303 adhere most, from the vapor deposition source 30 in comparison with a case in which the opening wall 23 is provided in parallel to the normal direction of the top wall 21. With this, the temperature of the adhesion portion of the vapor deposition objects 303 in the restriction unit 20 can be further decreased in comparison with the case in which the opening wall 23 is provided in parallel to the normal direction of the top wall 21, thereby making it possible to further enhance the effect of reduction in the re-adhesion of the vapor deposition objects 303 to the upper face 30a of the vapor deposition source 30.

The restriction unit 20 according to a fourth aspect of the present invention is such that, in the third aspect, the opening wall 23 may be provided stepwise.

With the above configuration, since the opening wall 23 is formed stepwise, processing thereof (formation of the opening wall 23) is carried out with ease. In addition, since the height, width, or the like of each step can be appropriately changed, the versatility can be further enhanced.

The restriction unit 20 according to a fifth aspect of the present invention is such that, in any one of the first through fourth aspects, a thickness of the opening wall 23 may be equal to a thickness of the top wall 21.

In this case, the processing is carried out with ease so that the restriction unit 20 can be produced with ease.

A vapor deposition device 100 according to a sixth aspect of the present invention includes the restriction unit 20 according to any one of the first through fifth aspects, and the vapor deposition source 30 that is disposed opposing the restriction unit 20 and emits the vapor deposition particles 301.

According to the above configuration, an effect similar to that of the first aspect can be obtained.

The vapor deposition device 100 according to a seventh aspect of the present invention is such that, in the sixth aspect, a distance α from a face (the lower face 23a) of the opening wall 23 opposing the vapor deposition source 30 to the upper face 30a of the vapor deposition source 30, may be not less than 1 mm and not greater than 100 mm.

In the case where the distance α is excessively short, the influence of the radiation heat from the vapor deposition source 30, particularly the influence of the radiation heat from the vapor deposition source 30 toward the lower face 23a of the opening wall 23 and the lower face of the side wall 22 becomes large. In the case where the plurality of openings mentioned above are provided and a plurality of emission openings (vapor deposition source openings 31) through which the vapor deposition particles 301 from the vapor deposition source 30 are emitted are provided corresponding to the respective openings, there is a possibility that the vapor deposition particles 301 emitted from the emission openings other than the emission openings corresponding to the respective openings flow into the respective openings if the distance α is excessively long. However, by making the distance α fall within the above-mentioned range, the influence of the radiation heat from the vapor deposition source 30 can be suppressed, and such a possibility does not arise, in the above-mentioned case, that the vapor deposition particles 301 emitted from the emission openings other than the emission openings corresponding to the respective openings flow into the respective openings.

A production method for a vapor deposition film according to an eighth aspect of the present invention is a method for forming the vapor deposition film 302 of a predetermined pattern on the target film forming substrate 200 using the vapor deposition device 100 according to the sixth or seventh aspect.

According to the above method, an effect similar to that of the first aspect can be obtained.

The production method for the vapor deposition film according to a ninth aspect of the present invention is such that, in the eighth aspect, the plurality of openings are provided in the restriction unit 20 being arranged in a first direction (X-axis direction) in plan view, and vapor deposition may be performed while relatively moving at least one of the target film forming substrate 200 and a set of the restriction unit 20 and the vapor deposition source 30 in a second direction (Y-axis direction) orthogonal to the first direction in plan view.

With the above method, the vapor deposition film 302 can be efficiently film-formed on the target film forming substrate 200 of large size using the restriction unit 20 smaller in size than the target film forming substrate 200.

A production method for an electroluminescence display device according to a tenth aspect of the present invention includes the production method for the vapor deposition film according to the eighth or ninth aspect.

With the above method, an effect similar to that of the eighth or ninth aspect can be obtained.

The production method for the electroluminescence display device according to an eleventh aspect of the present invention is such that, in the tenth aspect, the method includes a first electrode formation process (a preparation process of a TFT substrate and a first electrode (S1)) in which the first electrode 421 is formed on a substrate (TFT substrate 410), an electroluminescence layer formation process (a vapor deposition process of an organic EL layer (S2)) in which an electroluminescence layer (organic EL layer 422) that is formed of an organic or inorganic layer and includes at least the light emitting layer 422b is formed on the first electrode 421, and a second electrode formation process (a vapor deposition process of a second electrode (S3)) in which the second electrode 423 is formed on the electroluminescence layer, and at least the light emitting layer 422b is formed by the production method for the vapor deposition film according to the eighth or ninth aspect.

With the above method, abnormal film formation like the tiny film 304 can be prevented because the re-adhesion of the vapor deposition objects 303 to the vapor deposition source 30 caused by the re-evaporation of the vapor deposition objects 303 having adhered to the non-opening can be suppressed or prevented. Accordingly, the above-discussed production method makes it possible to form the light emitting layer 422b including a high resolution pattern without the adhesion of the tiny film 304 due to the re-evaporation of the vapor deposition objects 303. With this, according to the above-discussed production method, an EL display device, such as the organic EL display device 400, having higher display quality than the existing display device can be provided.

An electroluminescence display device according to a twelfth aspect of the present invention is an electroluminescence display device (organic EL display device 400) in which the first electrode 421, an electroluminescence layer (organic EL layer 422) formed of an organic or inorganic layer, and a second electrode 423 are provided in that order on a substrate (TFT substrate 410), wherein the electroluminescence layer includes the light emitting layer 422b formed of a pattern of the vapor deposition film 302 that is formed by the vapor deposition particles 301 having passed through an opening (restriction opening 24) of the restriction unit 20 including at least one opening configured to allow the vapor deposition particles 301 emitted from the vapor deposition source 30 to pass through and a plurality of non-openings (restriction sections 25) prepared at both sides of the above opening where the non-opening has a cross-sectional shape of an inverse concave formed of the top wall 21 and the opening walls 23.

The above configuration makes it possible to obtain an effect similar to that of the eleventh aspect.

The present invention is not limited to each of the embodiments stated above, and various modifications may be implemented within a range not departing from the scope of the claims. Embodiments obtained by appropriately combining technical approaches stated in each of the different embodiments also fall within the scope of the technology of the present invention. Moreover, novel technical features may be formed by combining the technical approaches stated in each of the embodiments.

### REFERENCE SIGNS LIST

1 Vapor deposition unit
2 Film formation chamber
3 Substrate carrying device
10 Vapor deposition mask
11 Mask opening region
12 Mask opening
13 Non-opening
20 Restriction unit
21 Top wall
21a, 23a, 502a Lower face
21b, 30a Upper face
22 Side wall
23 Opening wall
24 Restriction opening (opening)
25, 502 restriction section (non-opening)
30 Vapor deposition source
31 Vapor deposition source opening
100 Vapor deposition device
200 Target film forming substrate
201 Target deposition surface
202 Target film forming region
203 Target film forming pattern region
204 Non-film forming region
301 Vapor deposition particle
302 Vapor deposition film
303 Vapor deposition object
304 Tiny film
400 Organic EL display device
401 Pixel
402 Sub pixel
410 TFT substrate (substrate)
411 Insulating substrate
412 TFT
413 Signal line
414 Interlayer insulating film
414a Contact hole
415 Edge cover
415a Opening
420 Organic EL element
421 First electrode
422 Organic EL layer (electroluminescence layer)
422a Hole injection and transport layer (organic layer, inorganic layer)
422b Light emitting layer (organic layer, inorganic layer)
422c Electron transport and injection layer (organic layer, inorganic layer)
423 Second electrode
430 Sealing layer
500 Restriction unit
501 Restriction plate opening

1. A restriction unit configured to restrict a passage of vapor deposition particles emitted from a vapor deposition source, the unit comprising:
at least one opening configured to allow the vapor deposition particles to pass through; and
a plurality of non-openings prepared at both sides of the above opening,
wherein the non-opening has a cross-sectional shape of an inverse concave formed of a top wall and opening walls.

2. The restriction unit according to claim 1,
wherein the opening wall is provided in parallel to a normal direction of the top wall.

3. The restriction unit according to claim 1,
wherein the opening wall is provided being slanted relative to the normal direction of the top wall, and
the non-opening has a reversely tapered cross-sectional shape smaller in size on the top wall side than on the vapor deposition source side.

4. The restriction unit according to claim 3,
wherein the opening wall is formed stepwise.

5. The restriction unit according to claim 1,
wherein a thickness of the opening wall is equal to a thickness of the top wall.

6. A vapor deposition device comprising:
the restriction unit according to claim 1; and
the vapor deposition source disposed opposing the restriction unit and configured to emit the vapor deposition particles.

7. The vapor deposition device according to claim 6,
wherein a distance from a face of the opening wall opposing the vapor deposition source to an upper face of the vapor deposition source is not less than 1 mm and not greater than 100 mm.

8. A production method for a vapor deposition film, the method comprising:
forming a vapor deposition film of a predetermined pattern on a target film forming substrate by using the vapor deposition device according to claim 6.

9. The production method for the vapor deposition film according to claim 8,
wherein the at least one opening includes a plurality of openings, the plurality of openings are provided in the restriction unit being arranged in a first direction in plan view, and
vapor deposition is performed while relatively moving at least one of the target film forming substrate and a set of the restriction unit and the vapor deposition source in a second direction orthogonal to the first direction in plan view.

10. A production method for an electroluminescence display device, the method comprising:
the production method for the vapor deposition film according to claim 8.

11. The production method for the electroluminescence display device according to claim 10, the method further comprising:
forming a first electrode, the first electrode being formed on a substrate;
forming an electroluminescence layer, the electroluminescence layer formed of an organic or inorganic layer and including at least a light emitting layer being formed on the first electrode; and
forming a second electrode, the second electrode being formed on the electroluminescence layer,
wherein at least the light emitting layer is formed by the production method for the vapor deposition film.

12. An electroluminescence display device comprising:
a first electrode;
an electroluminescence layer formed of an organic or inorganic layer; and
a second electrode, the first electrode, the electroluminescence layer, and the second electrode being provided in that order on a substrate,
wherein the electroluminescence layer includes a light emitting layer formed of a pattern of a vapor deposition film formed by vapor deposition particles having passed through an opening of a restriction unit including at least one opening configured to allow the vapor deposition particles emitted from a vapor deposition source to pass through and a plurality of non-openings prepared at both sides of the above opening where the non-opening has a cross-sectional shape of an inverse concave formed of a top wall and opening walls.
